(19) United States
(12) Patent Application Publication
(10) Pub. No.: US 2024/0106196 A1
(43) Pub. Date: Mar. 28, 2024

(54) SEMICONDUCTOR LIGHT EMITTING DEVICE

(71) Applicant: ROHM CO., LTD., Kyoto-shi (JP)

(72) Inventors: Koki SAKAMOTO, Kyoto-shi (JP); Yoshinori TANAKA, Kyoto-shi (JP)

(21) Appl. No.: 18/529,665

(22) Filed: Dec. 5, 2023

Related U.S. Application Data
(63) Continuation of application No. PCT/JP2022/022039, filed on May 31, 2022.

(30) Foreign Application Priority Data
Jun. 9, 2021 (JP) 2021-096531

(51) Int. Cl. H01S 5/042; H01S 5/0231; H01S 5/024; H01S 5/068

(52) U.S. Cl. CPC H01S 5/042; H01S 5/0231; H01S 5/02469; H01S 5/06825; H01L 24/05

(57) ABSTRACT

A semiconductor light emitting device includes a light emitting module, a stem, and a surrounding member. The stem includes a conductive base and a conductive heat sink extending upright from the base. The light emitting module is mounted on the heat sink. The surrounding member is arranged on the base and surrounds the light emitting module and the heat sink. The light emitting module includes a substrate mounted on the heat sink, a light emitting element mounted on the substrate, and a light emitting element drive circuit mounted on the substrate. The light emitting element drive circuit includes a transistor configured to drive the light emitting element. The transistor is a vertical MOSFET mounted on the substrate.

### BACKGROUND

### 1. Field

The following description relates to a semiconductor light emitting device.

### 2. Description of Related Art

One type of semiconductor light emitting device is a semiconductor laser device. The semiconductor laser device includes a semiconductor laser element as a light source and is widely used as a light source device mounted on various electronic apparatuses. Japanese Laid-Open Patent Publication No. 2016-29718 discloses an example of a semiconductor laser device that includes a semiconductor laser chip and a stem.

### BRIEF DESCRIPTION OF THE DRAWINGS

FIG. 1 is a schematic perspective view showing a first embodiment of an exemplary semiconductor light emitting device.

FIG. 2 is a schematic cross-sectional view of the semiconductor light emitting device shown in FIG. 1.

FIG. 3 is a schematic perspective view of a stem and lead pins.

FIG. 4 is a schematic perspective view of the stem and the lead pins viewed from the side opposite to FIG. 3.

FIG. 5 is a schematic perspective view of the semiconductor light emitting device and a drive substrate.

FIG. 6 is a schematic plan view of a light emitting module in the first embodiment.

FIG. 7 is a perspective view of the light emitting module shown in FIG. 6.

FIG. 8 is a plan view showing an internal wiring structure of a substrate of the light emitting module shown in FIG. 6.

FIG. 9 is a plan view showing an internal wiring structure of the substrate of the light emitting module shown in FIG. 6.

FIG. 10 is a cross-sectional view taken along line 10-10 in FIG. 6.

FIG. 11 is a cross-sectional view taken along line 11-11 in FIG. 6.

FIG. 12 is a schematic circuit diagram showing the electrical configuration of a semiconductor light emitting device.

FIG. 13 is a graph showing optical output of a light emitting element corresponding to various source-drain resistances of a transistor (vertical MOSFET).

FIG. 14 is a graph plotting peak optical outputs of the light emitting element corresponding to the source-drain resistances shown in FIG. 13.

FIG. 15 is a graph plotting half-power pulse widths of pulse current applied to the light emitting element corresponding to the source-drain resistances shown in FIG. 13.

FIG. 16 is a schematic perspective view showing a second embodiment of an exemplary semiconductor light emitting device.

FIG. 17 is a plan view showing an internal wiring structure of a substrate of a light emitting module shown in FIG. 16.

FIG. 18 is a plan view showing an internal wiring structure of the substrate of the light emitting module shown in FIG. 16.

FIG. 19 is a plan view showing an internal wiring structure of the substrate of the light emitting module shown in FIG. 16.

FIG. 20 is a cross-sectional view of FIG. 16 taken along line 20-20 in FIG. 17.

FIG. 21 is a schematic plan view showing a modified example of a semiconductor light emitting device.

FIG. 22 is a schematic plan view of a light emitting module shown in FIG. 21.

FIG. 23 is a schematic cross-sectional view showing an example of the structure of a light receiving element embedded in a substrate.

FIG. 24 is a perspective view showing a modified example of a stem.

FIG. 25 is a schematic perspective view showing a modified example of a semiconductor light emitting device.

FIG. 26 is a graph showing a thermal conductivity analysis result of a semiconductor light emitting device that does not include a heat dissipation member.

FIG. 27 is a graph showing a thermal conductivity analysis result of a semiconductor light emitting device that includes a heat dissipation member.

FIG. 28 is a schematic perspective view showing a modified example of a semiconductor light emitting device.

FIG. 29 is a graph showing a thermal conductivity analysis result when the land of a drive substrate includes a via.

FIG. 30 is a schematic perspective view showing a modified example of a semiconductor light emitting device.

FIG. 31 is a graph showing a thermal conductivity analysis result in accordance with changes in the length of the heat dissipation member.

FIG. 32 is a graph showing a thermal conductivity analysis result in accordance with changes in the length of the heat dissipation member.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

Embodiments of a semiconductor light emitting device according to the present disclosure will be described below with reference to the drawings.

In the drawings, elements may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

In this specification, “at least one of A and B” should be understood to mean “only A, only B, or both A and B.”

### First Embodiment

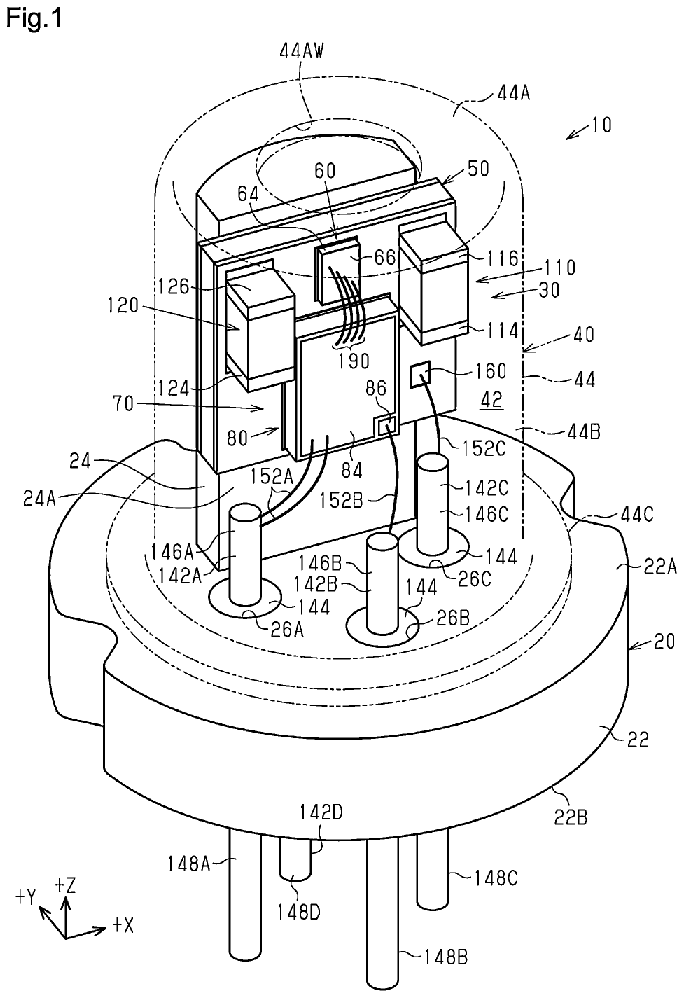

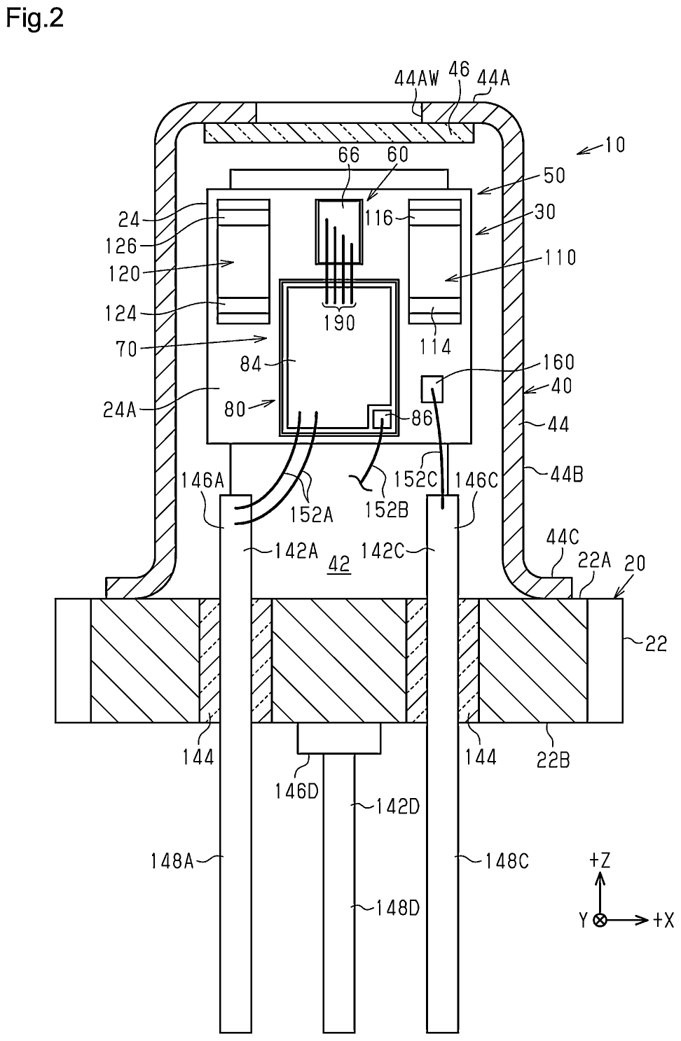

FIG. 1 is a schematic perspective view showing an example of a semiconductor light emitting device 10 according to the first embodiment. FIG. 2 is a cross-sectional view of the semiconductor light emitting device 10 shown in FIG. 1. In the present disclosure, for the sake of simplicity, components may be described based on the XYZ-axes that are orthogonal to each other in FIG. 1 and other drawings. In the following description, the +Z direction defines the upper side, and the —Z direction defines the lower side. The +X direction defines the right, and the —X direction defines the left.

The package structure will now be described.

As shown in FIGS. 1 and 2, the semiconductor light emitting device 10 includes a stem 20, a light emitting module 30 mounted on the stem 20, and a surrounding member 40. The stem 20 includes a base 22 and a heat sink 24 extending upright from the base 22. The light emitting module 30 is mounted on the heat sink 24. The surrounding member 40 is arranged on the base 22 and surrounds the light emitting module 30 and the heat sink 24. The structure for packaging the light emitting module 30 using the stem 20 and the surrounding member 40 may be referred to as a CAN package structure.

The surrounding member 40 defines an accommodation cavity 42 configured to accommodate the light emitting module 30. The surrounding member 40 is fixed to the base 22 of the stem 20. The surrounding member 40 and the stem 20 hermetically seal the accommodation cavity 42 in a hollow state to form a hollow sealing structure.

In the first embodiment, the surrounding member 40 includes a cap 44 and a light-transmissive plate 46 (refer to FIG. 2). The light-transmissive plate 46 may be omitted depending on the usage of the semiconductor light emitting device 10. The material of the cap 44 is not limited. In an example, the cap 44 is formed from a metal material that blocks light such as iron (Fe) or an Fe alloy. In the first embodiment, the cap 44 includes a top portion 44A, a tube 44B, and a flange 44C. The top portion 44A, the tube 44B, and the flange 44C are formed integrally.

The tube 44B is, for example, circular. The top portion 44A is located on one end (upper end in FIGS. 1 and 2) of the tube 44B. The flange 44C is located on the other end of (lower end in FIGS. 1 and 2) of the tube 44B. The flange 44C is fixed to a front surface 22A of the base 22 by, for example, welding or using a bonding material. The top portion 44A includes a window 44AW that allows for transmission of light emitted from the light emitting module 30. The window 44AW is, for example, circular.

The light-transmissive plate 46 is fixed to the top portion 44A from the inside of the cap 44 by a bonding material or the like and blocks the window 44AW. The light-transmissive plate 46 is formed from, for example, a transparent material such as glass and allows for transmission of light through the window 44AW. The light-transmissive plate 46 is also used as a sealing member that seals the accommodation cavity 42 for the light emitting module 30 surrounded by the surrounding member 40.

An overview of the light emitting module 30 will now be described.

The light emitting module 30 includes a substrate 50, a light emitting element 60, and a light emitting element drive circuit 70. The light emitting element 60 and the light emitting element drive circuit 70 are mounted on the substrate 50. The light emitting element 60 is a laser diode (semiconductor laser element). The light emitting element drive circuit 70 includes a transistor 80 configured to drive the light emitting element 60. The transistor 80 is a metal-oxide-semiconductor field-effect transistor (MOSFET) having a vertical structure and is mounted on the substrate 50. In the present disclosure, the MOSFET having a vertical structure is referred to as a vertical MOSFET.

In the first embodiment, the light emitting element drive circuit 70 further includes a first capacitor 110 and a second capacitor 120. The type of the first and second capacitors 110 and 120 is not limited. In an example, relatively low-cost ceramic capacitors may be used. The light emitting element drive circuit 70 supplies electric charge, which is stored in the first and second capacitors 110 and 120, as pulse current to the light emitting element 60 through the transistor 80 to drive the light emitting element 60.

The structure of the stem 20 will now be described.

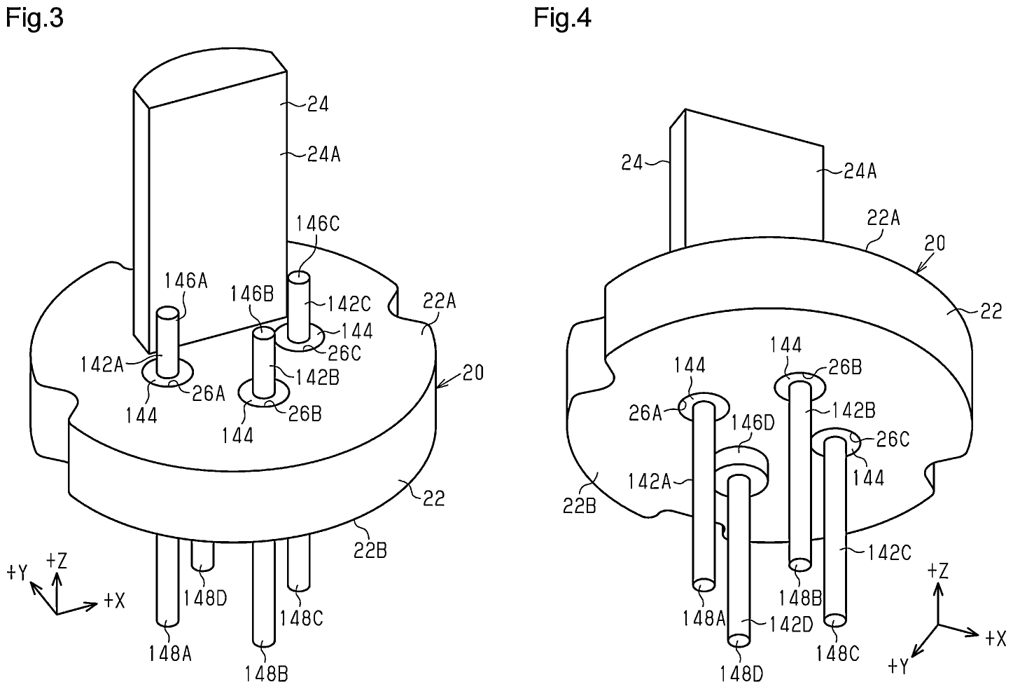

FIG. 3 is a schematic perspective view showing the structure of the stem 20. FIG. 4 is a perspective view of the stem 20 viewed from the side opposite to FIG. 3.

As described above, the stem 20 includes the base 22 and the heat sink 24. In the first embodiment, the base 22 and the heat sink 24 are formed integrally. In an example, the stem 20 is formed from a conductive material such as copper (Cu), a Cu alloy, Fe, or an Fe alloy. Alternatively, the base 22 and the heat sink 24 may be formed from different metals.

The base 22 is, for example, circular as viewed in a thickness-wise direction of the base 22. In the present disclosure, the thickness-wise direction of the base 22 refers to a direction (Z-axis direction) orthogonal to the front surface 22A of the base 22. The size of the base 22 is not limited. In an example, the diameter of the base 22 is approximately 5.6 mm, and the thickness is approximately 1.2 mm.

The heat sink 24 is formed integrally with the front surface 22A of the base 22. The heat sink 24 is, for example, sectoral as viewed in the thickness-wise direction of the base 22. The size of the heat sink 24 is not limited. In an example, the height (dimension in Z-axis direction) of the heat sink 24 from the front surface 22A of the base 22 is approximately 4.45 mm. The thickness (dimension in Y-axis direction) of the heat sink 24 is approximately 0.75 mm at the maximum.

The heat sink 24 includes a flat support surface 24A. The light emitting module 30 is mounted on the support surface 24A. In an example, the light emitting module 30 is bonded to the support surface 24A by a conductive bonding material (not shown) and is electrically connected to the heat sink 24 by the conductive bonding material. In the first embodiment, the heat sink 24 is electrically connected to the transistor 80 of the light emitting module 30 by a conductive bonding material. The conductive bonding material may be, for example, a conductive paste such as silver (Ag) paste.

Multiple through holes extend through the base 22 in the thickness-wise direction of the base 22. In the first embodiment, for example, three through holes 26A, 26B, and 26C extend through the base 22. The through holes 26A, 26B, and 26C are, for example, circular as viewed in the thickness-wise direction of the base 22. The size of the through holes 26A, 26B, and 26C is not limited. In an example, each of through holes 26A, 26B, and 26C has a diameter of approximately 1.0 mm.

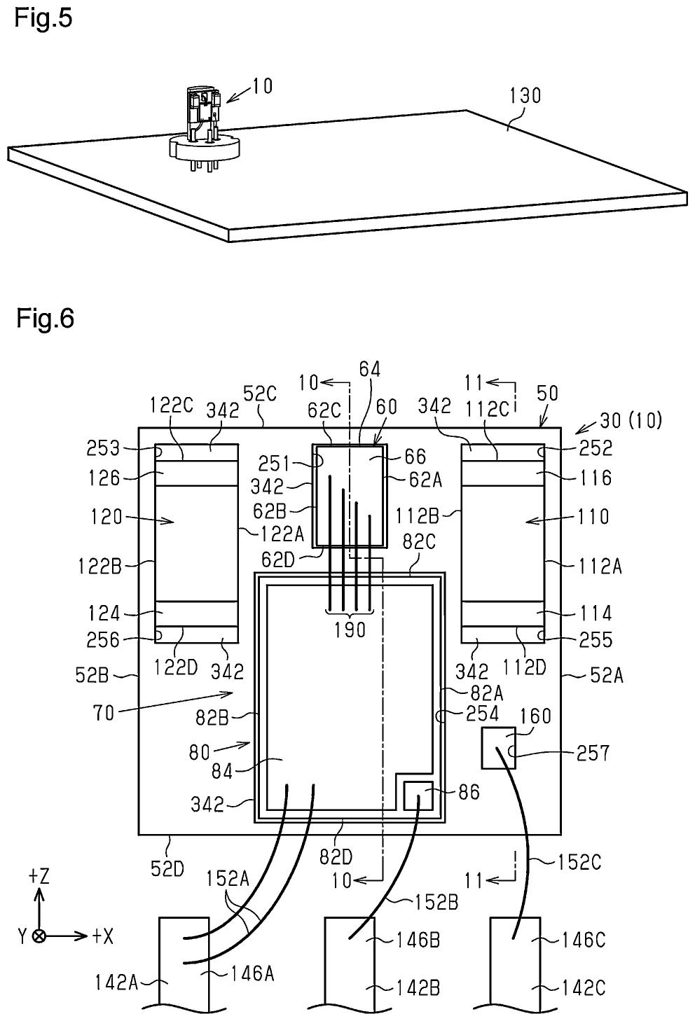

FIG. 5 is a schematic perspective view showing an example in which the semiconductor light emitting device 10 is mounted. The semiconductor light emitting device 10 is mounted on a drive substrate 130 controlling driving of the light emitting module 30. The semiconductor light emitting device 10 includes multiple lead pins electrically connected to the light emitting module 30 and the drive substrate 130. In the first embodiment, the semiconductor light emitting device 10 includes, for example, four lead pins 142A, 142B, 142C, and 142D. In the first embodiment, each of the lead pins 142A and 142B corresponds to a first lead pin. The lead pin 142D corresponds to a second lead pin. The lead pin 142C corresponds to a third lead pin.

As shown in FIGS. 1, 3, and 4, the lead pins 142A, 142B, and 142C extend through the base 22. In the first embodiment, the lead pins 142A, 142B, and 142C are inserted through the through holes 26A, 26B, and 26C in the base 22. An insulation member 144 fills the through holes 26A, 26B, and 26C to electrically insulate the lead pins 142A, 142B, 142C from the base 22. The insulation member 144 is formed of, for example, glass.

The lead pins 142A, 142B, and 142C include connectors 146A, 146B, and 146C and terminals 148A, 148B, and 148C. The connectors 146A, 146B, and 146C are the portions projecting from the front surface 22A of the base 22. The terminals 148A, 148B, and 148C are the portions projecting from a back surface 22B of the base 22. The lengths of the connectors 146A, 146B, and 146C are not limited. In an example, the length of each of the connectors 146A, 146B, and 146C is approximately 1.0 mm.

As shown in FIGS. 2 and 4, the lead pin 142D includes a connector 146D and a terminal 148D. The connector 146D is arranged on one end of the terminal 148D and is bonded to the back surface 22B of the base 22. Thus, the lead pin 142D is fixed to the base 22. The lead pin 142D is fixed to a position where the lead pin 142D overlaps the heat sink 24 as viewed in the thickness-wise direction of the base 22. The lead pin 142D is electrically connected to the transistor 80 of the light emitting module 30 by the base 22 and the heat sink 24.

The terminals 148A, 148B, 148C, and 148D of the lead pins 142A, 142B, 142C, and 142D are used when the semiconductor light emitting device 10 is mounted on the drive substrate 130. The length of each of the terminals 148A, 148B, 148C, and 148D is not limited. In an example, the length of each of the terminals 148A, 148B, 148C, and 148D is approximately 6.5 mm before the semiconductor light emitting device 10 is mounted on the drive substrate 130, and is approximately 1.0 mm when the semiconductor light emitting device 10 is mounted on the drive substrate 130.

The length of the terminals 148A, 148B, 148C, and 148D when the semiconductor light emitting device 10 is mounted on the drive substrate 130 corresponds to the distance between the back surface 22B of the base 22 and the drive substrate 130. As the distance increases, the length of the terminals 148A, 148B, 148C, and 148D increases. This increases thermal resistance in the lead pins 142A, 142B, 142C, and 142D. Such thermal resistance causes an increase in the temperature of the light emitting element 60. Hence, it is desirable that the distance between the back surface 22B of the base 22 and the drive substrate 130 be short.

The connectors 146A, 146B, and 146C of the lead pins 142A, 142B, and 142C are electrically connected to the light emitting module 30 by wires 152A, 152B, and 152C (refer to FIG. 1), respectively. In an example, the wires 152A, 152B, and 152C may be formed from a metal material such as gold (Au). In the first embodiment, the connector 146A is, for example, electrically connected to the transistor 80 of the light emitting module 30 by two wires 152A. The connector 146B is, for example, electrically connected to the transistor 80 of the light emitting module 30 by one wire 152B. The connector 146C is, for example, electrically connected to an external element connection pad 160 arranged on the substrate 50 of the light emitting module 30 by one wire 152C.

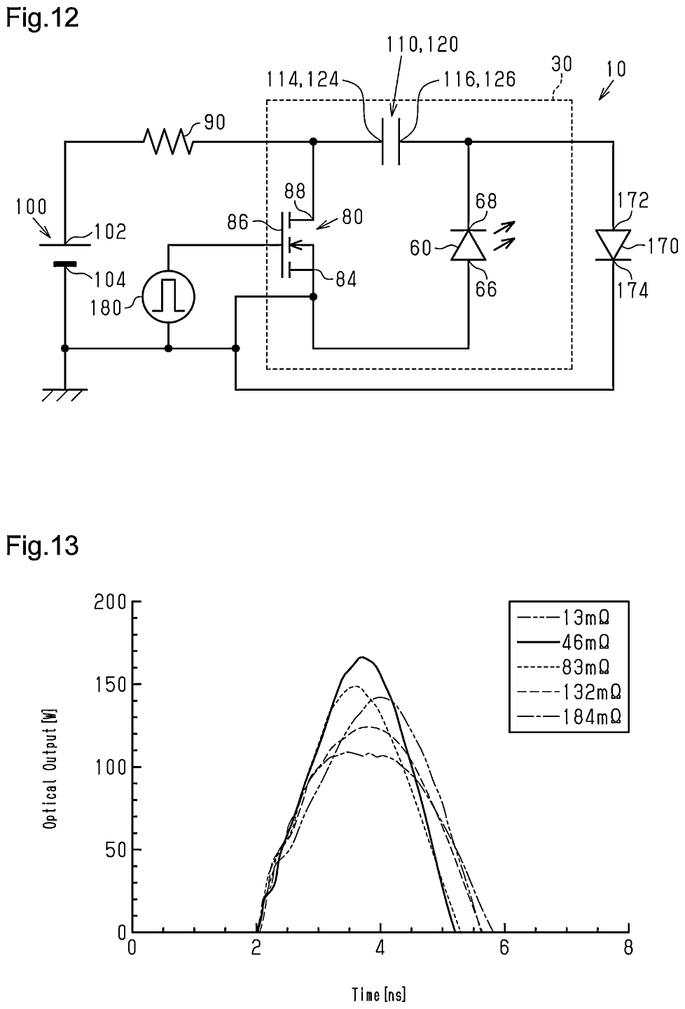

The external element connection pad 160 is used to connect an external element to the substrate 50 (light emitting module 30). In the first embodiment, the external element connected to the external element connection pad 160 is a Schottky diode 170 (SBD) (refer to FIG. 12) arranged on the drive substrate 130. The SBD 170 is connected in antiparallel to the light emitting element 60 and is used as a protection diode of the light emitting element 60 to hamper the flow of reverse current to the light emitting element 60, which will be described later.

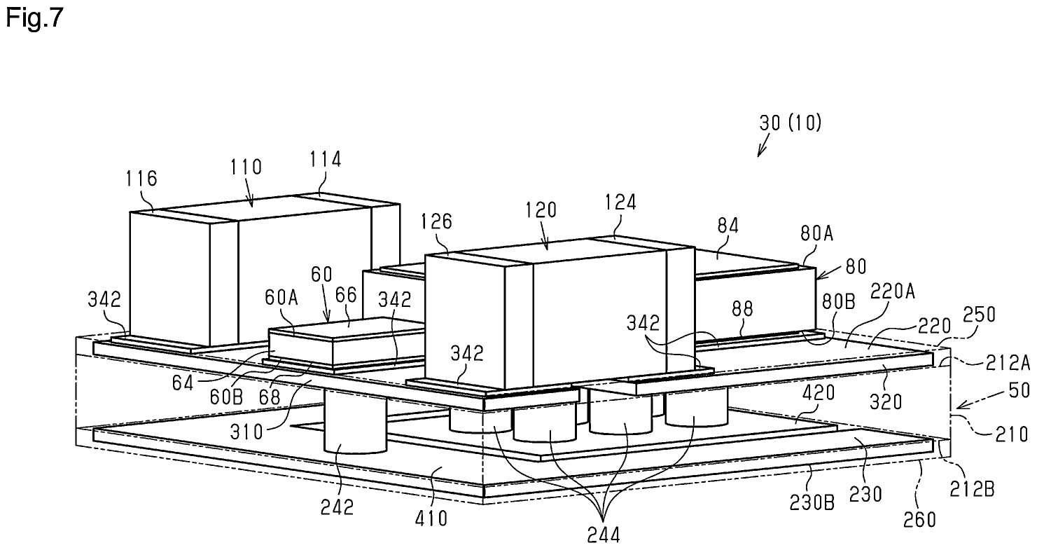

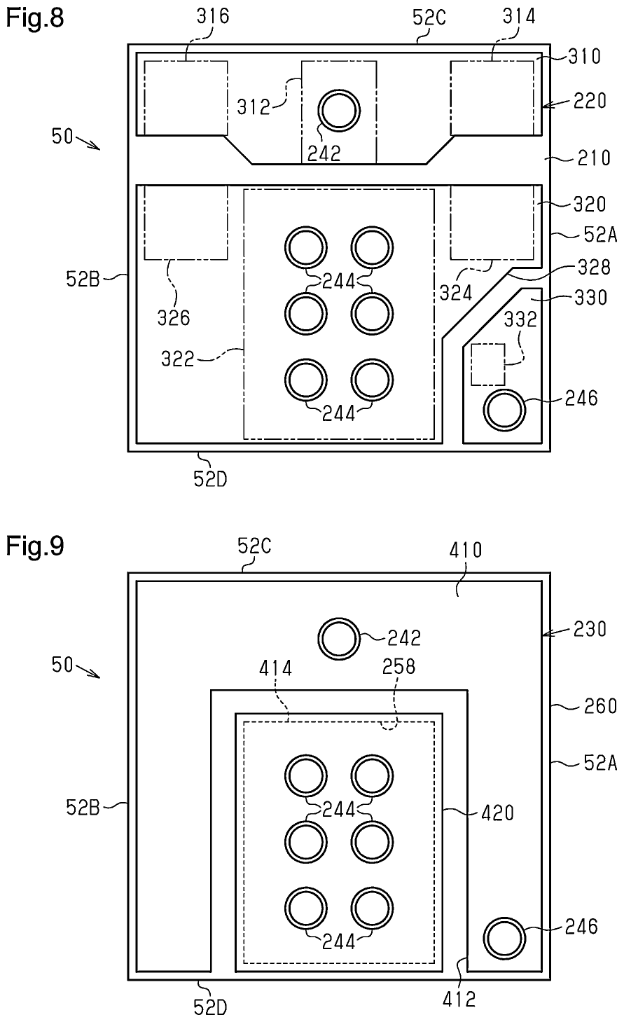

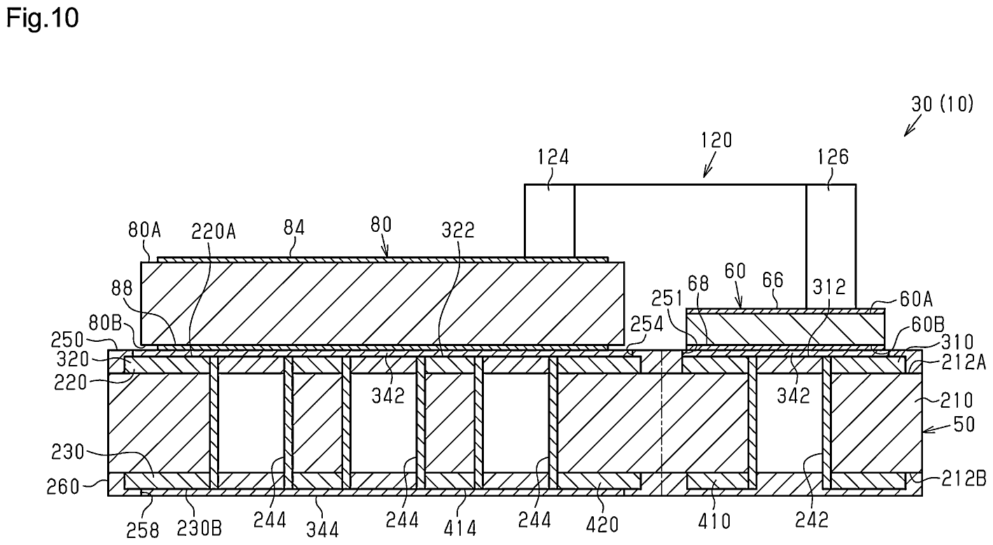

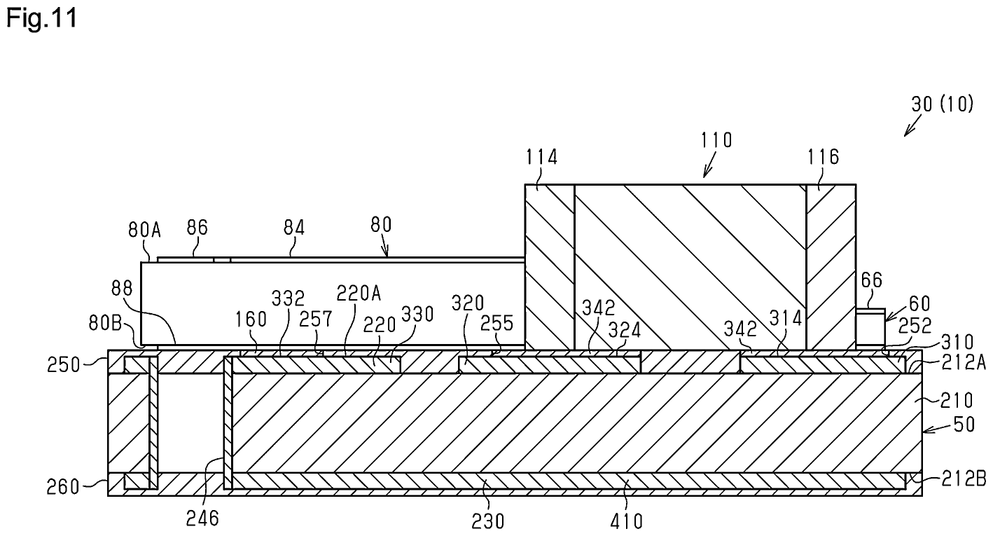

FIG. 6 is a schematic plan view of the light emitting module 30 in the first embodiment. FIG. 7 is a perspective view of the light emitting module 30. FIGS. 8 and 9 are plan views showing an internal wiring structure of the substrate 50 of the light emitting module 30. FIG. 10 is a cross-sectional view taken along line 10-10 in FIG. 6. FIG. 11 is a cross-sectional view taken along line 11-11 in FIG. 6.

As shown in FIG. 6, the substrate 50 is rectangular. The size of the substrate 50 is not limited. In an example, the substrate 50 is substantially square and includes a first side 52A and a second side 52B, which are parallel to each other and have a length (dimension in the Z-axis direction) of approximately 2.5 mm, and a third side 52C and a fourth side 52D, which are parallel to each other and connect the first side 52A and the second side 52B and have a length (dimension in the X-axis direction) of approximately 2.6 mm. The thickness of the substrate 50 is, for example, approximately 0.3 mm. The term “parallel” used in the present disclosure includes not only a state in which two objects are completely parallel to each other but also a state in which two objects are substantially parallel to each other.

The light emitting element 60, which is a laser diode, the transistor 80, which drives the light emitting element 60, the first capacitor 110, and the second capacitor 120 are mounted on the substrate 50. Each of the light emitting element 60, the transistor 80, the first capacitor 110, and the second capacitor 120 is rectangular in a plan view of the substrate 50. In the present disclosure, the plan view of the substrate 50 refers to a view of an object in the thickness-wise direction (Y-axis direction) of the substrate 50.

In the first embodiment, in the plan view of the substrate 50, the light emitting element 60 is rectangular and includes a first side 62A and a second side 62B parallel to each other and a third side 62C and a fourth side 62D parallel to each other and connecting the first side 62A and the second side 62B. In the light emitting element 60, the third side 62C and the fourth side 62D are shorter than the first side 62A and the second side 62B. The light emitting element 60 is arranged so that the third side 62C of the light emitting element 60 is parallel and adjacent to the third side 52C of the substrate 50. In the plan view of the substrate 50, the light emitting element 60 is located closer to the third side 52C of the substrate 50 than the center of the substrate 50.

As shown in FIG. 6, the light emitting element 60 includes a light outputting end surface 64 at the third side 62C of the light emitting element 60. A laser beam is emitted from the light outputting end surface 64 in a direction (substantially +Z direction) that is orthogonal to the light outputting end surface 64.

As shown in FIGS. 7 and 10, the light emitting element 60 includes an anode electrode 66, which is arranged on a front surface 60A of the light emitting element 60, and a cathode electrode 68, which is arranged on a back surface 60B of the light emitting element 60. The cathode electrode 68 is bonded to the substrate 50.

As shown in FIG. 6, in the plan view of the substrate 50, in the first embodiment, the transistor 80 is rectangular and includes a first side 82A and a second side 82B parallel to each other and a third side 82C and a fourth side 82D parallel to each other and connecting the first side 82A and the second side 82B. In the transistor 80, the third side 82C and the fourth side 82D are shorter than the first side 82A and the second side 82B. The transistor 80 is arranged so that the fourth side 82D of the transistor 80 is parallel and adjacent to the fourth side 52D of the substrate 50. The transistor 80 is also arranged so that the third side 82C of the transistor 80 is parallel and adjacent to the fourth side 62D of the light emitting element 60.

As shown in FIGS. 7 and 10, the transistor 80, which is a vertical MOSFET, includes a source electrode 84, which is arranged on a portion of a front surface 80A of the transistor 80, and a gate electrode 86 (refer to FIG. 6), which is arranged on another portion of the front surface 80A of the transistor 80. The source electrode 84 is greater in size than the gate electrode 86. The transistor 80 further includes a drain electrode 88 arranged on substantially the entity of a back surface 80B of the transistor 80. The drain electrode 88 is bonded to the substrate 50.

The gate electrode 86 of the transistor 80 is electrically connected to the connector 146B of the lead pin 142B by the wire 152B, described above. A control voltage for controlling the switching of the transistor 80 is applied to a gate electrode 86 from the gate driver 180 (refer to FIG. 12) arranged on the drive substrate 130 through the lead pin 142B and the wire 152B.

The source electrode 84 of the transistor 80 is electrically connected to the connector 146A of the lead pin 142A by the two wires 152A, described above. Ground voltage is applied to the source electrode 84 from the drive substrate 130 through the lead pin 142A and the wires 152A.

The source electrode 84 of the transistor 80 is, for example, electrically connected to the anode electrode 66 of the light emitting element 60 by multiple wires 190, in the first embodiment, four wires 190. The wires 190 form a wiring path that connects the transistor 80 and the light emitting element 60. When the transistor 80 is activated, current flows from the transistor 80 to the light emitting element 60 through the wiring path. The number of wires 190 may be increased to facilitate the flow of current from the transistor 80 to the light emitting element 60. This limits the effect of parasitic inductance. In an example, the number of wires 190 is set to be greater than the total number of wires 152A and 152B. The wires 190 may be ribbon cables. In the first embodiment, the wires 152A and 152B correspond to a first wire. The wire 190 correspond to a second wire.

As shown in FIG. 6, in the plan view of the substrate 50, in the first embodiment, the first capacitor 110 is rectangular and includes a first side 112A and a second side 112B parallel to each other and a third side 112C and a fourth side 112D parallel to each other and connecting the first side 112A and the second side 112B. In the first capacitor 110, the third side 112C and the fourth side 112D are shorter than the first side 112A and the second side 112B. The first capacitor 110 is arranged so that the first side 112A of the first capacitor 110 is parallel and adjacent to the first side 52A of the substrate 50 and the third side 112C of the first capacitor 110 is parallel and adjacent to the third side 52C of the substrate 50. The first capacitor 110 is also arranged so that the second side 112B of the first capacitor 110 is parallel and adjacent to the first side 82A of the transistor 80.

As shown in FIGS. 6, 7, and 11, the first capacitor 110 includes a first electrode 114 arranged on one end of the first capacitor 110 and a second electrode 116 arranged on the other end of the first capacitor 110. The first and second electrodes 114 and 116 are bonded to the substrate 50.

The first electrode 114 of the first capacitor 110 is electrically connected to the drain electrode 88 of the transistor 80 by the internal wiring structure of the substrate 50. The second electrode 116 of the first capacitor 110 is electrically connected to the cathode electrode 68 of the light emitting element 60 by the internal wiring structure of the substrate 50.

As shown in FIG. 6, in the plan view of the substrate 50, in the first embodiment, the second capacitor 120 is rectangular and includes a first side 122A and a second side 122B parallel to each other and a third side 122C and a fourth side 122D parallel to each other and connecting the first side 122A and the second side 122B. In the second capacitor 120, the third side 122C and the fourth side 122D are shorter than the first side 122A and the second side 122B. The second capacitor 120 is arranged so that the second side 122B of the second capacitor 120 is parallel and adjacent to the second side 52B of the substrate 50 and so that the third side 122C of the second capacitor 120 is parallel and adjacent to the third side 52C of the substrate 50. The second capacitor 120 is also arranged so that the first side 122A of the second capacitor 120 is parallel and adjacent to the second side 82B of the transistor 80.

As shown in FIGS. 6, 7, and 10, the second capacitor 120 includes a first electrode 124 arranged on one end of the second capacitor 120 and a second electrode 126 arranged on the other end of the second capacitor 120. The first and second electrodes 124 and 126 are bonded to the substrate 50.

The first electrode 124 of the second capacitor 120 is electrically connected to the drain electrode 88 of the transistor 80 by the internal wiring structure of the substrate 50. The second electrode 126 of the second capacitor 120 is electrically connected to the cathode electrode 68 of the light emitting element 60 by the internal wiring structure of the substrate 50.

As described above, while the first capacitor 110 is arranged adjacent to the first side 82A of the transistor 80, the second capacitor 120 is arranged adjacent to the second side 82B of the transistor 80. In this arrangement, the third side 82C of the transistor 80 is located between the first capacitor 110 and the second capacitor 120 so that the transistor 80 is located close to the light emitting element 60. Thus, the distance between the transistor 80 and the light emitting element 60 in the substrate 50 is decreased. This results in a decrease in the length of the wiring path (wires 190) connecting the light emitting element 60 and the transistor 80, thereby limiting the effect of parasitic inductance.

In addition, the first capacitor 110 and the second capacitor 120 are arranged on the substrate 50 to be symmetrical about the light emitting element 60 and the transistor 80. Thus, a first wiring path through which current flows from the first capacitor 110 to the light emitting element 60 via the transistor 80 and a second wiring path through which current flows from the second capacitor 120 to the light emitting element 60 via the transistor 80 are symmetrically arranged about the light emitting element 60 and the transistor 80.

The first wiring path includes a wiring path connecting the first electrode 114 of the first capacitor 110 to the drain electrode 88 of the transistor 80, the wires 190 connecting the source electrode 84 of the transistor 80 and the anode electrode 66 of the light emitting element 60, and a wiring path connecting the cathode electrode 68 of the light emitting element 60 and the second electrode 116 of the first capacitor 110. The wiring paths described above are formed of the internal wiring structure of the substrate 50.

The second wiring path includes a wiring path connecting the first electrode 124 of the second capacitor 120 and the drain electrode 88 of the transistor 80, the wires 190 connecting the source electrode 84 of the transistor 80 and the anode electrode 66 of the light emitting element 60, and a wiring path connecting the cathode electrode 68 of the light emitting element 60 and the second electrode 126 of the second capacitor 120. The wiring paths described above are formed of the internal wiring structure of the substrate 50.

The symmetrical arrangement of the first wiring path and the second wiring path cancels out the magnetic flux formed by a current flowing through the first wiring path and the magnetic flux formed by a current flowing through the second wiring path. This reduces parasitic inductance present in the first wiring path and parasitic inductance present in the second wiring path.

The structure of the substrate 50 of the light emitting module 30 will now be described.

As shown in FIGS. 6 to 11, the substrate 50 is, for example, a printed wiring board. In the first embodiment, the internal wiring structure of the substrate 50 is a two-layer wiring structure. The substrate 50 includes an insulative base member 210, a first wiring layer 220 arranged on a front surface 212A of the base member 210, and a second wiring layer 230 arranged on a back surface 212B of the base member 210. The base member 210 is formed from, for example, an insulative material such as a resin member, a silicon member, a glass member, or a ceramic member. In the first embodiment, a resin member formed from a glass-epoxy resin is used as the base member 210. The first wiring layer 220 and the second wiring layer 230 are formed from, for example, a metal material such as Cu.

As shown in FIGS. 7 to 11, the substrate 50 includes multiple via wirings extending through the base member 210 and electrically connecting the first wiring layer 220 and the second wiring layer 230. In the first embodiment, the substrate 50 includes a first via wiring 242, multiple (for example, six) second via wirings 244, and a third via wiring 246. The first to third via wirings 242, 244, and 246 are formed from, for example, a metal material such as Cu.

The substrate 50 further includes a first insulation layer 250 and a second insulation layer 260. The first insulation layer 250 is arranged on a front surface 220A of the first wiring layer 220 and partially exposes the first wiring layer 220. The second insulation layer 260 is arranged on a back surface 230B of the second wiring layer 230 and partially exposes the second wiring layer 230. The first insulation layer 250 and the second insulation layer 260 are formed from, for example, an insulating material such as silicon dioxide (SiO₂). To facilitate understanding, in FIG. 7, the base member 210, the first insulation layer 250, and the second insulation layer 260 are indicated by imaginary lines (double-dashed lines).

FIG. 8 is a plan view of the first wiring layer 220 and the base member 210. FIG. 8 does not show the first insulation layer 250.

As shown in FIG. 8, the first wiring layer 220 includes multiple wiring patterns that are arranged separately from each other on the front surface 212A of the base member 210. In the first embodiment, the first wiring layer 220 includes a first front wiring pattern 310, a second front wiring pattern 320, and a third front wiring pattern 330.

The first front wiring pattern 310 is arranged along the first, second, third sides 52A, 52B, and 52C of the substrate 50 and has an area of, for example, approximately ⅓ of the area of the substrate 50. The first front wiring pattern 310 includes first to third wiring regions 312, 314, and 316. Each of the first to third wiring regions 312, 314, and 316 is a portion of the first front wiring pattern 310. Physical interfaces of the first to third wiring regions 312, 314, and 316 do not exist in the first front wiring pattern 310.

The first wiring region 312 refers to a light emitting element mount region on which the cathode electrode 68 of the light emitting element 60 is mounted. The second wiring region 314 is a portion of a first capacitor mount region on which the second electrode 116 of the first capacitor 110 is mounted. The third wiring region 316 is a portion of the first capacitor mount region on which the second electrode 126 of the second capacitor 120 is mounted. Thus, the cathode electrode 68 of the light emitting element 60 is electrically connected to the second electrodes 116 and 126 of the first and second capacitors 110 and 120 by the first front wiring pattern 310. The second wiring region 314 and the third wiring region 316 are symmetrically arranged about the first wiring region 312.

The second front wiring pattern 320 is arranged along the first, second, and fourth sides 52A, 52B, and 52D of the substrate 50 and is separated from the first front wiring pattern 310. The second front wiring pattern 320 is, for example, slightly smaller than approximately ⅔ of the area of the substrate 50. The second front wiring pattern 320 includes fourth to sixth wiring regions 322, 324, and 326. Each of the fourth to sixth wiring regions 322, 324, and 326 is a portion of the second front wiring pattern 320. Physical interfaces of the fourth to sixth wiring regions 322, 324, and 326 do not exist in the second front wiring pattern 320.

The fourth wiring region 322 is a transistor mount region on which the drain electrode 88 of the transistor 80 is mounted. The fifth wiring region 324 is a portion of the first capacitor mount region on which the first electrode 114 of the first capacitor 110 is mounted. The sixth wiring region 326 is a portion of a second capacitor mount region on which the first electrode 124 of the second capacitor 120 is mounted. Thus, the drain electrode 88 of the transistor 80 is electrically connected to the first electrodes 114 and 124 of the first and second capacitors 110 and 120 by the second front wiring pattern 320. The fifth wiring region 324 and the sixth wiring region 326 are symmetrically arranged about the fourth wiring region 322.

The second front wiring pattern 320 further includes a cutaway portion 328. The cutaway portion 328 is formed adjacent to the fourth wiring region 322 (the transistor mount region) and the fifth wiring region 324 (portion of the first capacitor mount region) of the second front wiring pattern 320.

The third front wiring pattern 330 is arranged along the first and fourth sides 52A and 52D of the substrate 50 and is separated from the second front wiring pattern 320. In the first embodiment, the third front wiring pattern 330 is arranged adjacent to (but separated from) the cutaway portion 328 of the second front wiring pattern 320. The total area of the second front wiring pattern 320 and the third front wiring pattern 330 corresponds to approximately ⅔ of the area of the substrate 50. In other words, the second front wiring pattern 320 and the third front wiring pattern 330 are separated from each other so that a combined form of the second front wiring pattern 320 and the third front wiring pattern 330 is rectangular and has approximately ⅔ of the area of the substrate 50.

The third front wiring pattern 330 includes a seventh wiring region 332. The seventh wiring region 332 is a portion of the third front wiring pattern 330. A physical interface of the seventh wiring region 332 does not exist in the third front wiring pattern 330. The seventh wiring region 332 is an external element connection region for connecting an external element to the substrate 50 (the light emitting element drive circuit 70). The external element connection pad 160 (refer to FIG. 6) is disposed in the seventh wiring region 332. In the first embodiment, the seventh wiring region 332 (the external element connection pad 160) is connected to an anode electrode 172 of the SBD 170 (refer to FIG. 12) by the lead pin 142C and the wire 152C (refer to FIG. 6).

The first insulation layer 250 includes first to seventh openings 251 to 257 (refer to FIG. 6) respectively exposing the first to seventh wiring regions 312, 314, 316, 322, 324, 326, and 332 of the first to third front wiring patterns 310, 320, and 330. A first metal plating material 342 (refer to FIGS. 6, 7, 10, and 11) is arranged on the first to sixth wiring regions 312, 314, 316, 322, 324, and 326 exposed from the first to sixth openings 251 to 256 in the first insulation layer 250. As shown in FIG. 10, the cathode electrode 68 of the light emitting element 60 is bonded to the first wiring region 312 (the light emitting element mount region) by the first metal plating material 342. The drain electrode 88 of the transistor 80 is bonded to the fourth wiring region 322 (the transistor mount region) by the first metal plating material 342. As shown in FIG. 11, the first and second electrodes 114 and 116 of the first capacitor 110 are respectively bonded to the fifth and second wiring regions 324 and 314 (the first capacitor mount region) by the first metal plating material 342. Although a cross-sectional view is not shown, in the same manner as the first capacitor 110, the first and second electrodes 124 and 126 of the second capacitor 120 are respectively bonded to the sixth and third wiring regions 326 and 316 (the second capacitor mount region) by the first metal plating material 342. The first metal plating material 342 is formed from solder plating. Examples of the solder plating may be, for example, lead (Pb)-free solder such as tin (Su)-silver (Ag)-copper (Cu)-based solder.

The external element connection pad 160 (refer to FIGS. 6 and 11) is arranged in the seventh wiring region 332 exposed from the seventh opening 257 in the first insulation layer 250. The external element connection pad 160 is formed from a second metal plating material. The second metal plating material may be, for example, a metal material that includes nickel (Ni), palladium (Pd), and gold (Au).

FIG. 9 is a plan view of the second wiring layer 230 and the second insulation layer 260. FIG. 9 does not show the first insulation layer 250, the first wiring layer 220, and the base member 210.

As shown in FIG. 9, the second wiring layer 230 includes multiple wiring patterns arranged separately from each other on the back surface 212B (refer to FIG. 7) of the base member 210. In the first embodiment, the second wiring layer 230 includes a first back wiring pattern 410 and a second back wiring pattern 420.

The first back wiring pattern 410 is arranged along the first to fourth sides 52A, 52B, 52C, and 52D of the substrate 50. The first back wiring pattern 410 is generally C-shaped. In plan view, an opening 412 is formed in the first back wiring pattern 410. In a plan view of the substrate 50, the opening 412 is located in a position corresponding to the fourth wiring region 322 (the transistor mount region) of the second front wiring pattern 320 and is greater in size than the fourth wiring region 322. In a plan view of the substrate 50, the first back wiring pattern 410 overlaps the first and third front wiring patterns 310 and 330 and a portion of the second front wiring pattern 320.

The second back wiring pattern 420 is arranged in the opening 412, which is located inside the first back wiring pattern 410, along the fourth side 52D of the substrate 50. The second back wiring pattern 420 includes an eighth wiring region 414. The eighth wiring region 414 is a portion of the second back wiring pattern 420. A physical interface of the eighth wiring region 414 does not exist in the second back wiring pattern 420. The eighth wiring region 414 is a transistor connection region for electrically connecting the drain electrode 88 of the transistor 80 to the heat sink 24 (refer to, for example, FIG. 1). In a plan view of the substrate 50, the second back wiring pattern 420 overlaps the second front wiring pattern 320.

The second insulation layer 260 has an eighth opening 258 exposing the eighth wiring region 414 (the transistor connection region) of the second back wiring pattern 420. As shown in FIG. 10, a third metal plating material 344 is arranged on the eighth wiring region 414 exposed from the eighth opening 258. Thus, the eighth wiring region 414 is bonded to the heat sink 24 by the third metal plating material 344. In an example, the third metal plating material 344 is solder plating. In an example, the same material as the first metal plating material 342 may be used.

The second insulation layer 260 covers the back surface 230B of the second wiring layer 230 except for the eighth wiring region 414 (the transistor connection region). Thus, the first back wiring pattern 410 is not exposed from the second insulation layer 260 and is not electrically connected to the heat sink 24.

As shown in FIGS. 7 to 11, the first to third via wirings 242, 244, and 246 extend through the base member 210 and electrically connect the first wiring layer 220 and the second wiring layer 230. In the first embodiment, each of the via wirings 242, 244, and 246 is, for example, circular and tubular, however, is not limited to a particular shape. The via wirings 242, 244, and 246 are thermal vias that are used as a conductive path between the first wiring layer 220 and the second wiring layer 230 and as a heat dissipation path from the first wiring layer 220 to the second wiring layer 230.

The first via wiring 242 is arranged in the first wiring region 312 (the light emitting element mount region) and electrically connects the first front wiring pattern 310 and the first back wiring pattern 410. The cathode electrode 68 of the light emitting element 60 and the second electrodes 116 and 126 of the first and second capacitors 110 and 120 are electrically connected to the first back wiring pattern 410 by the first front wiring pattern 310 and the first via wiring 242.

The second via wirings 244 are arranged in the fourth wiring region 322 (the transistor mount region) and the eighth wiring region 414 (the transistor mount region) and electrically connect the second front wiring pattern 320 and the second back wiring pattern 420. Thus, the drain electrode 88 of the transistor 80 is electrically connected to the heat sink 24 of the stem 20 by the second front wiring pattern 320, the second via wirings 244, and the second back wiring pattern 420. Also, the drain electrode 88 of the transistor 80 is electrically connected to the first electrodes 114 and 124 of the first and second capacitors 110 and 120 by the second front wiring pattern 320. The layout pattern of the second via wirings 244 is not limited. In an example, the second via wirings 244 are regularly arranged in the fourth and eighth wiring regions 322 and 414. In the first embodiment, for example, the second via wirings 244 are arranged in an array of 2×3.

The third via wiring 246 electrically connects the third front wiring pattern 330 and the first back wiring pattern 410. Thus, the anode electrode 172 of the SBD 170 (refer to FIG. 12), which is connected to the external element connection pad 160, is electrically connected to the second electrodes 116 and 126 of the first and second capacitors 110 and 120 by the third front wiring pattern 330, the third via wiring 246, the first back wiring pattern 410, the first via wiring 242, and the first front wiring pattern 310. Also, the second electrodes 116 and 126 of the first and second capacitors 110 and 120 are electrically connected to the cathode electrode 68 of the light emitting element 60. Thus, the anode electrode 172 of the SBD 170 is electrically connected to the cathode electrode 68 of the light emitting element 60.

FIG. 12 is a schematic circuit diagram showing the electrical configuration of the semiconductor light emitting device 10.

The light emitting element drive circuit 70 includes the light emitting element 60, the transistor 80 (vertical MOSFET), the first capacitor 110, and the second capacitor 120, which are mounted on the substrate 50 of the light emitting module 30. In FIG. 12, the first capacitor 110 and the second capacitor 120 are indicated as one capacitor.

The drain electrode 88 of the transistor 80 is connected to the first electrodes 114 and 124 of the first and second capacitors 110 and 120. The drain electrode 88 of the transistor 80 and the first electrodes 114 and 124 of the first and second capacitors 110 and 120 are connected to a positive electrode 102 of a constant voltage source 100 by a resistance element 90. The constant voltage source 100 includes a negative electrode 104 connected to ground. In the first embodiment, the constant voltage source 100 and the resistance element 90 are arranged on the drive substrate 130 (refer to FIG. 5). Voltage is applied from the constant voltage source 100 to the drain electrode 88 of the transistor 80 and the first electrodes 114 and 124 of the first and second capacitors 110 and 120 through the resistance element 90, the lead pin 142D (refer to FIGS. 1 and 2), the base 22 and the heat sink 24 of the stem 20, and the internal wiring structure of the substrate 50.

The source electrode 84 of the transistor 80 is connected to the anode electrode 66 of the light emitting element 60 and is also connected to ground. In the first embodiment, ground voltage is applied from the drive substrate 130 to the source electrode 84 of the transistor 80 through the lead pins 142A (FIGS. 1 and 2) and the wires 152A. The source electrode 84 of the transistor 80 is also connected to the anode electrode 66 of the light emitting element 60 by the wires 190 (refer to FIGS. 1 and 2).

The gate electrode 86 of the transistor 80 is connected to the gate driver 180, arranged on the drive substrate 130. In the first embodiment, a control voltage is applied from the gate driver 180 to the gate electrode 86 of the transistor 80 through the lead pin 142B (refer to FIGS. 1 and 6) and the wire 152B. The control voltage controls activation and deactivation of the transistor 80.

The cathode electrode 68 of the light emitting element 60 is connected to the second electrodes 116 and 126 of the first and second capacitors 110 and 120. In the first embodiment, the cathode electrode 68 of the light emitting element 60 is connected to the second electrodes 116 and 126 of the first and second capacitors 110 and 120 by the internal wiring structure of the substrate 50.

The cathode electrode 68 of the light emitting element 60 and the second electrodes 116 and 126 of the first and second capacitors 110 and 120 are connected to the anode electrode 172 of the SBD 170. In the first embodiment, the SBD 170 is arranged on the drive substrate 130. The anode electrode 172 of the SBD 170 is connected to the external element connection pad 160 by the lead pin 142C (refer to FIGS. 1 and 2) and the wire 152C. The external element connection pad 160 is connected to the cathode electrode 68 of the light emitting element 60 and the second electrodes 116 and 126 of the first and second capacitors 110 and 120 by the internal wiring structure of the substrate 50.

The SBD 170 includes a cathode electrode 174 connected to a negative electrode 104 of the constant voltage source 100. In the first embodiment, the cathode electrode 174 of the SBD 170 is also connected to the anode electrode 66 of the light emitting element 60 by the lead pin 142A (refer to FIGS. 1 and 2), the wire 152A, the source electrode 84 of the transistor 80, and the wires 190.

When the transistor 80 is deactivated by the control voltage from the gate driver 180, the constant voltage source 100, the resistance element 90, the first and second capacitors 110 and 120, and the SBD 170 form a closed loop circuit. Thus, the first and second capacitors 110 and 120 are charged from the voltage supplied from the constant voltage source 100.

When the transistor 80 is activated by the control voltage from the gate driver 180, the transistor 80, the light emitting element 60, and the first and second capacitors 110 and 120 form a closed loop circuit. As a result, current (pulse current) based on the charge stored in the first and second capacitors 110 and 120 flows through the transistor 80 to the light emitting element 60 so that the light emitting element 60 emits a laser beam.

The chip area of the transistor 80 (vertical MOSFET) will now be described.

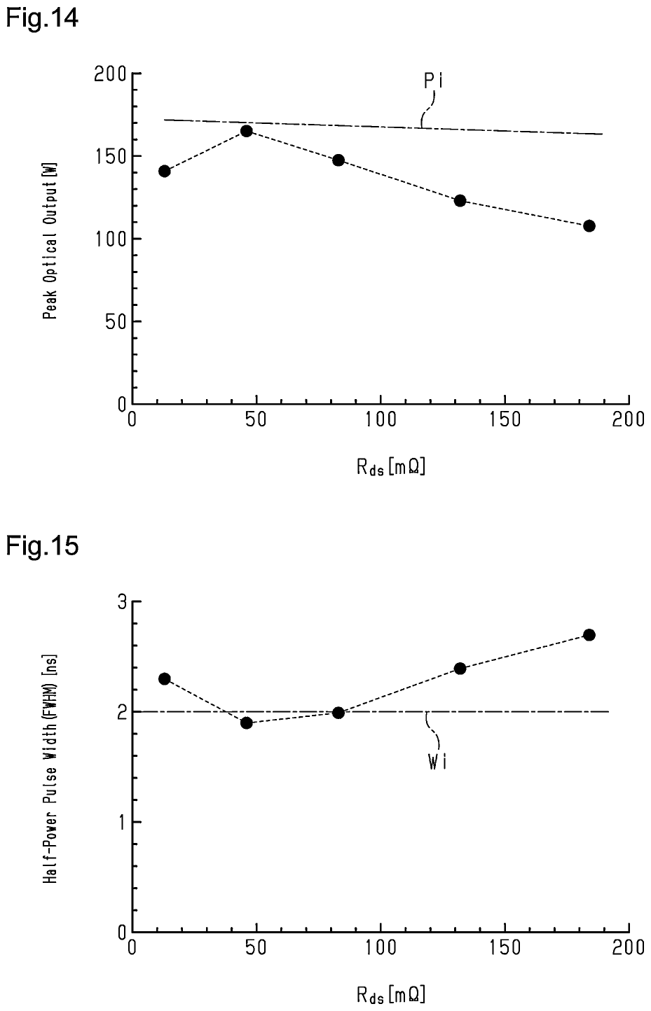

FIG. 13 is a graph showing optical outputs of the light emitting element 60 corresponding to various source-drain resistances Rds of the transistor 80. FIG. 14 is a graph plotting peak optical outputs corresponding to the source-drain resistances Rds shown in FIG. 13.

The source-drain resistance Rds of the transistor 80 depends on the chip area of the transistor 80. As the chip area of the transistor 80 increases, the source-drain resistance Rds decreases. In the examples shown in FIGS. 13 and 14, the optical output of the light emitting element 60 is shown when the source-drain resistance Rds of the transistor 80 is 13 mΩ, 46 mΩ, 83 mΩ, 132 mΩ, and 184 mΩ. These values of the source-drain resistance Rds are measured when the gate-source voltage of the transistor 80 is sufficiently high (in this example, the gate-source voltage is 10\).

As shown in FIGS. 13 and 14, when the source-drain resistance Rds of the transistor 80 is 46 mΩ, the optical output of the light emitting element 60 is the maximum peak optical output. In FIG. 14, the single-dashed line indicates a target value Pi of peak optical output calculated for the light emitting element drive circuit 70 based on an RLC (resistor, inductor, capacitor) current equation. The target value Pi is calculated on the assumption that the transistor 80 has no switching loss and the saturation current of the transistor 80 is sufficiently large relative to pulse current supplied to the light emitting element 60 from the first and second capacitors 110 and 120. As shown in FIG. 14, when the source-drain resistance Rds is 13 mΩ, 46 mΩ, and 83 mΩ, the peak optical output is close to the target value Pi. When the source-drain resistance Rds is 46 mΩ, the peak optical output is the closest to the target value Pi.

FIG. 15 is a graph plotting half-power pulse widths (full width at half maximum: FWHM) of pulse current corresponding to the various source-drain resistances Rds shown in FIG. 13. In FIG. 15, the single-dashed line indicates a target value Wi (in this example, 2 ns) of the half-power pulse width (FWHM) calculated for the light emitting element drive circuit 70 based on an RLC current equation. The target value Wi is also calculated on the assumption that the transistor 80 has no switching loss and the saturation current of the transistor 80 is sufficiently large relative to pulse current supplied to the light emitting element 60 from the first and second capacitors 110 and 120. As shown in FIG. 15, when the source-drain resistance Rds is 13 mΩ, 46 mΩ, and 83 mΩ, the half-power pulse width is close to the target value Wi. When the source-drain resistance Rds is 46 mΩ, the half-power pulse width is the closest to the target value Wi.

As described above, the graph in FIG. 14 shows that when the chip area of the transistor 80 is increased to decrease the source-drain resistance Rds, the saturation current of the transistor 80 is increased. This increases the current flowing to the light emitting element 60 and increases the optical output. The graph in FIG. 15 shows that when the chip area of the transistor 80 is increased to decrease the source-drain resistance Rds, an increase in the half-power pulse width is limited. However, as the chip area of the transistor 80 is increased, the parasitic capacitance will increase in the transistor 80. This increases switching loss. The increase in switching loss decreases the optical output and increases the half-power pulse width. The trade-off relationship between increases in saturation current and decreases in switching loss is taken into consideration to determine the source-drain resistance Rds (chip area of the transistor 80) that obtains a satisfactory peak optical output and a satisfactory half-power pulse width. The graphs in FIGS. 14 and 15 show that a satisfactory peak optical output and a satisfactory half-power pulse width are obtained when the source-drain resistance Rds is 13 mΩ, 46 mΩ, and 83 mΩ.

When the source-drain resistance Rds is 46 mΩ, the chip area of the transistor 80 is approximately 1.6 mm² (in this example, 1.1 mm×1.46 mm) When the source-drain resistance Rds is 13 mΩ, the chip area of the transistor 80 is approximately 4.3 mm². When the source-drain resistance Rds is 83 mΩ, the chip area of the transistor 80 is approximately 0.8 mm². Therefore, it is preferred from the viewpoint of obtaining a satisfactory peak optical output and a satisfactory half-power pulse width that the chip area of the transistor 80 be greater than or equal to 0.8 mm² and less than or equal to 4.3 mm².

The operation of the semiconductor light emitting device 10 of the first embodiment will now be described.

The light emitting module 30 is mounted on the heat sink 24 of the stem 20. The surrounding member 40 is arranged on the base 22 of the stem 20 to surround the light emitting module 30 and the heat sink 24. The light emitting module 30 includes the light emitting element 60 and the light emitting element drive circuit 70. The light emitting element drive circuit 70 includes the transistor 80 configured to drive the light emitting element 60. The transistor 80 is a vertical MOSFET and is mounted on the substrate 50, which is mounted on the heat sink 24.

Since the transistor 80 is a vertical MOSFET, the source electrode 84 overlaps the drain electrode 88 in a plan view of the substrate 50. The use of the vertical MOSFET shortens the wiring path of the transistor 80, mounted on the substrate 50, as compared to when a lateral MOSFET is used. This allows for reduction in the size of the substrate 50 and, accordingly, the size of the light emitting module 30.

The semiconductor light emitting device 10 of the first embodiment has the following advantages.

(1-1) The semiconductor light emitting device 10 includes the stem 20, the light emitting module 30, and the surrounding member 40. The stem 20 includes the conductive base 22 and the conductive heat sink 24 extending upright from the base 22. The light emitting module 30 is mounted on the heat sink 24. The surrounding member 40 is arranged on the base 22 and surrounds the light emitting module 30 and the heat sink 24. The light emitting module 30 includes the substrate 50, which is mounted on the heat sink 24, and the light emitting element 60 and the light emitting element drive circuit 70, which are mounted on the substrate 50. The light emitting element drive circuit 70 includes a transistor 80 configured to drive the light emitting element 60. The transistor 80 is a vertical MOSFET and is mounted on the substrate 50. This structure shortens the wiring path of the transistor 80, mounted on the substrate 50, thereby reducing the size of the light emitting module 30, mounted on the stem 20.

(1-2) The use of the vertical MOSFET as the transistor 80 shortens the wiring path of the transistor 80, mounted on the substrate 50, thereby allowing for an increase in the chip area of the transistor 80. Thus, the source-drain resistance Rds of the transistor 80 is decreased. This increases the saturation current of the transistor 80, thereby increasing the optical output and decreasing the half-power pulse width (i.e., high-speed response and improved noise resistance as a result of short pulse). However, there is a trade-off between increases in saturation current and decreases in switching loss. An increase in the chip area of the transistor 80 increases switching loss. In addition, as the chip area of the transistor 80 increases, the light emitting module 30 proportionally increases in size. Therefore, the trade-off between increase in saturation current and decrease in switching loss and the overall size of the light emitting module 30 are taken into consideration when determining the chip area of the transistor 80. In the first embodiment, the chip area of the transistor 80 is greater than or equal to 0.8 mm² and less than or equal to 4.3 mm² so that both high output and short pulse are achieved.

(1-3) The use of a vertical MOSFET as the transistor 80 shortens each wiring path for current flowing from the first and second capacitors 110 and 120 to the light emitting element 60 through the transistor 80 as compared to when a lateral MOSFET is used. This decreases parasitic inductance produced in the wiring path.

(1-4) The light emitting element drive circuit 70 includes the first and second capacitors 110 and 120 mounted on the substrate 50. In this structure, the transistor 80 and the first and second capacitors 110 and 120 are collected in the light emitting module 30. In addition, the use of the vertical MOSFET, which shortens the wiring path of the transistor 80 on the substrate 50, decreases wiring inductance. As a result, a relatively low-cost ceramic capacitor may be used as the first and second capacitors 110 and 120 instead of using a high-cost low-inductance silicon capacitor. This reduces the cost of the light emitting module 30.

(1-5) In a plan view of the substrate 50, the first capacitor 110 is mounted on the substrate 50 adjacent to the first side 82A of the transistor 80. In a plan view of the substrate 50, the second capacitor 120 is mounted on the substrate 50 adjacent to the second side 82B of the transistor 80. Thus, the third side 82C of the transistor 80 is located between the first capacitor 110 and the second capacitor 120. The light emitting element 60 is arranged adjacent to the third side 82C of the transistor 80 and electrically connected to the transistor 80 by the wires 190. This structure allows the transistor 80 to be arranged close to the light emitting element 60. This shortens the wires 190, thereby shortening the wiring path for current flowing from the transistor 80 to the light emitting element 60. As a result, parasitic inductance in the wiring path is decreased.

(1-6) The first capacitor 110 and the second capacitor 120 are symmetrically arranged about the light emitting element 60 and the transistor 80. Thus, the first wiring path, through which current flows from the first capacitor 110 to the light emitting element 60 via the transistor 80 and the wires 190, and the second wiring path, through which current flows from the second capacitor 120 to the light emitting element 60 via the transistor 80 and the wires 190, are symmetrically arranged about the light emitting element 60 and the transistor 80. This arrangement cancels out the magnetic flux formed by current flowing through the first wiring path and the magnetic flux formed by current flowing through the second wiring path. This reduces parasitic inductance present in the first wiring path and parasitic inductance present in the second wiring path.

(1-7) The light emitting element drive circuit 70 supplies current to the light emitting element 60 using the first capacitor 110 and the second capacitor 120. This structure increases the current supplied to the light emitting element 60.

(1-8) The third side 82C of the transistor 80 is shorter than the first side 82A and the second side 82B of the transistor 80. The distance between the first capacitor 110 and the second capacitor 120 is greater than the length of the third side 82C of the transistor 80. In this structure, the short side (third side 82C) of the transistor 80 is located between the first and second capacitors 110 and 120. This shortens each wiring path for current flowing from the first and second capacitors 110 and 120 to the light emitting element 60 via the transistor 80, thereby decreasing parasitic inductance in the wiring path.

(1-9) The drive substrate 130, configured to control the driving of the light emitting module 30, is electrically connected to the light emitting module 30 by the lead pins 142A, 142B, 142C, and 142D. Thus, the driving of the light emitting module 30 is controlled by the drive substrate 130 via the lead pins 142A, 142B, 142C, and 142D. Additionally, the lead pins 142A, 142B, 142C, and 142D form a path that dissipates heat from the light emitting module 30 to the drive substrate 130.

(1-10) The number of the wires 190, which connect the transistor 80 to the light emitting element 60, is greater than the number of the wires 152A and 152B, which connect the transistor 80 to the lead pins 142A and 142B. This allows the current to readily flow from the transistor 80 to the light emitting element 60 and results in a decrease in parasitic inductance.

(1-11) The lead pin 142D is fixed to the base 22 and is electrically connected to the transistor 80 by the base 22, the heat sink 24, and the internal wiring structure of the substrate 50. Thus, when heat is produced in the transistor 80, the heat is dissipated from the heat sink 24 through the base 22 and the lead pin 142D.

(1-12) The substrate 50 includes the first and second via wirings 242 and 244, which extend through the base member 210 and electrically connect the first wiring layer 220 to the second wiring layer 230. The first wiring layer 220 includes the first front wiring pattern 310, which includes the first wiring region 312 (the light emitting element mount region), and the second front wiring pattern 320, which includes the fourth wiring region 322 (the transistor mount region). The second wiring layer 230 includes the first back wiring pattern 410 and the second back wiring pattern 420, which includes the eighth wiring region 414 (the transistor connection region). The first via wiring 242 electrically connects the first front wiring pattern 310 and the first back wiring pattern 410. The second via wirings 244 electrically connect the second front wiring pattern 320 and the second back wiring pattern 420. The first back wiring pattern 410 is arranged on the heat sink 24 with the second insulation layer 260 located between the first back wiring pattern 410 and the heat sink 24. The second back wiring pattern 420 is arranged on the heat sink 24 with the eighth wiring region 414 (the transistor connection region), exposed from the second insulation layer 260, electrically connected to the heat sink 24. In this structure, the light emitting element 60 and the transistor 80 (vertical MOSFET) are mounted on the substrate 50, and the transistor 80 is electrically connected to the heat sink 24. In addition, the first via wiring 242, which forms a path for dissipating heat from the light emitting element 60, and the second via wirings 244, which form a path for dissipating heat from the transistor 80, increase the heat dissipation property of the light emitting module 30.

(1-13) The first via wiring 242 is arranged in only the first wiring region 312 (the light emitting element mount region), which is located directly below the light emitting element 60. The first via wiring 242 is a portion of the wiring path connecting the cathode electrode 68 of the light emitting element 60 to the external element connection pad 160 and electrically connects the first front wiring pattern 310 to the first back wiring pattern 410. If the first via wiring 242 is arranged outside the first wiring region 312, the first via wiring 242 may interfere with a current flowing from the cathode electrode 68 of the light emitting element 60 to the second electrodes 116 and 126 of the first and second capacitors 110 and 120 through the first front wiring pattern 310. This is because an increase in the number of the first via wirings 242 increases the leakage of current from the first front wiring pattern 310 through the first via wirings 242. As a result, the increase in the number of the first via wirings 242 interferes with the current flowing from the first electrodes 114 and 124 of the first and second capacitors 110 and 120 to the light emitting element 60 through the transistor 80 and the wires 190. In the first embodiment, only one first via wiring 242 is arranged in the first wiring region 312, which is located directly below the light emitting element 60. This limits interference of the first via wiring 242 with the current flowing to the light emitting element 60.

(1-14) The first wiring layer 220 includes the third front wiring pattern 330 separated from the second front wiring pattern 320. The substrate 50 includes the third via wiring 246, which electrically connects the third front wiring pattern 330 and the first back wiring pattern 410. In this structure, the external element connection pad 160 may be arranged on the third front wiring pattern 330, and the SBD 170 (protection diode) may be connected to the external element connection pad 160. The third front wiring pattern 330 is connected to the first back wiring pattern 410 by the third via wiring 246. The first back wiring pattern 410 is connected to the first front wiring pattern 310 by the first via wiring 242. The light emitting element 60 is connected to the first front wiring pattern 310. Thus, when the first front wiring pattern 310 and the third front wiring pattern 330 are located at different positions and the SBD 170 is connected to the third front wiring pattern 330, the SBD 170 is connected to the light emitting element 60. In this structure, free space of the substrate 50 is used for arrangement of the external element connection pad 160. This avoids an increase in the size of the substrate 50 resulting from arrangement of the external element connection pad 160.

### Second Embodiment

A second embodiment of a semiconductor light emitting device 10 will now be described. The second embodiment differs from the first embodiment in the internal wiring structure of the substrate 50 of the light emitting module 30 but otherwise has the same structure as the first embodiment. The description of the second embodiment will focus on the differences from the first embodiment. The same reference characters are given to those components that are the same as the corresponding components of the first embodiment.

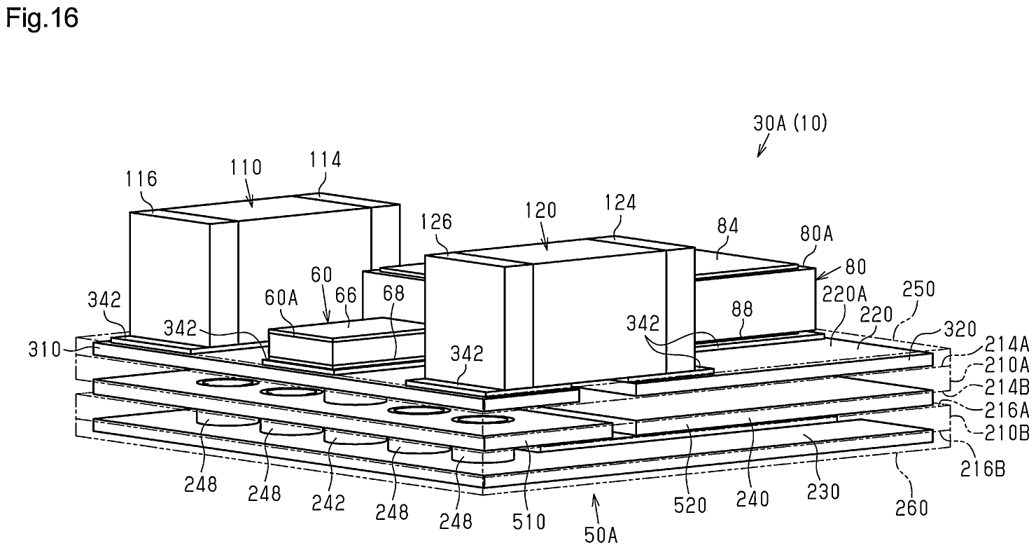

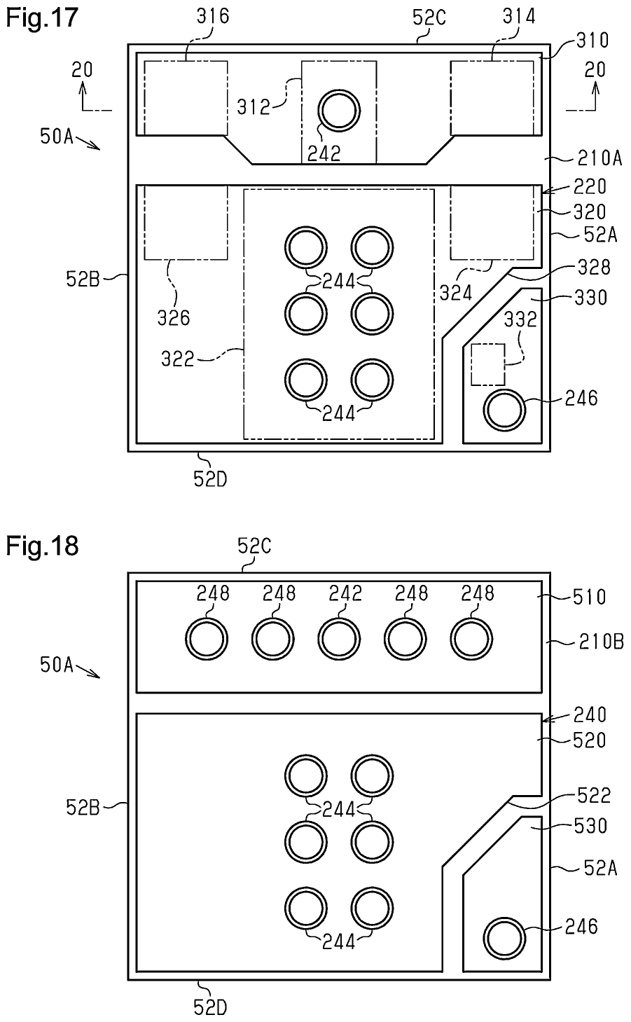

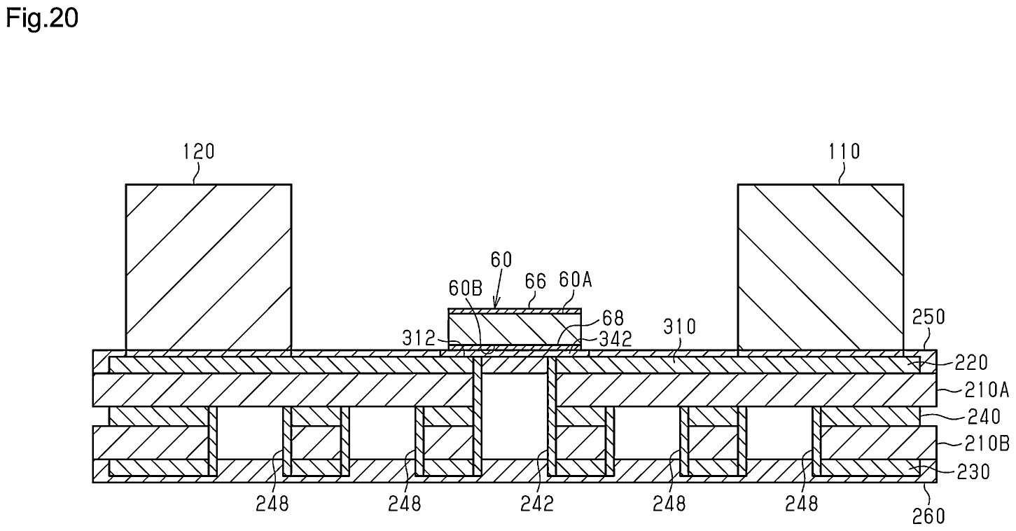

FIG. 16 is a schematic perspective view of a light emitting module 30A in the second embodiment. FIGS. 17 to 19 are cross-sectional views showing the internal wiring structure of a substrate 50A of the light emitting module 30A. FIG. 20 is a cross-sectional view of FIG. 16 taken along line 20-20 in FIG. 17.

As shown in FIGS. 16 to 20, the substrate 50A of the light emitting module 30A is, for example, a printed wiring board. In the second embodiment, the internal wiring structure of the substrate 50A is a three-layer wiring structure.

The substrate 50A includes an insulative first base member 210A, the first wiring layer 220 arranged on a front surface 214A of the first base member 210A, an insulative second base member 210B, and the second wiring layer 230 arranged on a back surface 216B of the second base member 210B. The substrate 50A includes an intermediate wiring layer 240 arranged between a back surface 214B of the first base member 210A and a front surface 216A of the second base member 210B.

More specifically, in the second embodiment, the base member 210 of the first embodiment is separated into the first base member 210A and the second base member 210B, and the intermediate wiring layer 240 is arranged between the first base member 210A and the second base member 210B. In other words, the substrate 50A of the second embodiment has a structure in which the intermediate wiring layer 240 is arranged in the base member 210 of the first embodiment. The intermediate wiring layer 240 is formed from, for example, a metal material such as Cu as in the first and second wiring layers 220 and 230.

The first base member 210A and the second base member 210B are formed from, for example, an insulative material such as a resin member, a silicon member, a glass member, or a ceramic member. In the second embodiment, a resin member formed from a glass-epoxy resin is used as the first base member 210A and the second base member 210B.

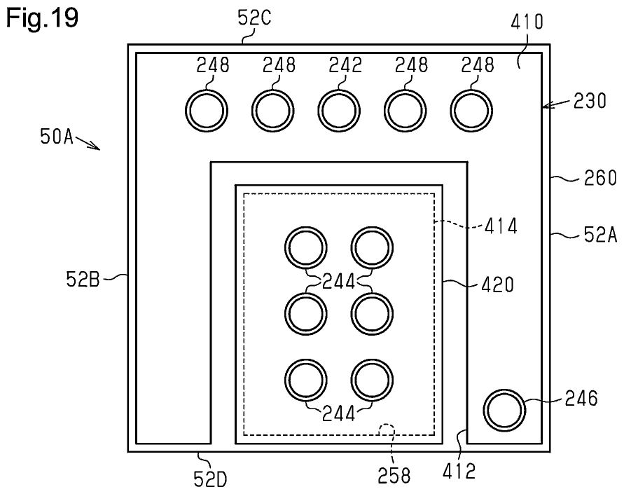

The structure of the first wiring layer 220 and the structure of the second wiring layer 230 are the same as those of the first embodiment. Hence, as shown in FIG. 17, the first wiring layer 220 includes the first to third front wiring patterns 310, 320, and 330. The first front wiring pattern 310 includes the first to third wiring regions 312, 314, and 316. The second front wiring pattern 320 includes the fourth to sixth wiring regions 322, 324, and 326. The third front wiring pattern 330 includes the seventh wiring region 332. As shown in FIG. 19, the second wiring layer 230 includes the first and second back wiring patterns 410 and 420. The second back wiring pattern 420 includes the eighth wiring region 414.

As shown in FIG. 18, the intermediate wiring layer 240 includes a first intermediate wiring pattern 510, a second intermediate wiring pattern 520, and a third intermediate wiring pattern 530.

The first intermediate wiring pattern 510 is arranged along the first, second, and third sides 52A, 52B, and 52C of the substrate 50A and has an area of, for example, approximately ⅓ of the area of the substrate 50A. In a plan view of the substrate 50A, the first intermediate wiring pattern 510 overlaps the first front wiring pattern 310 and the first back wiring pattern 410.

The second intermediate wiring pattern 520 is arranged along the first, second, and fourth sides 52A, 52B, and 52D of the substrate 50A and is separated from the first intermediate wiring pattern 510. The second intermediate wiring pattern 520 is, for example, slightly smaller than approximately ⅔ of the area of the substrate 50A. In the second embodiment, the second intermediate wiring pattern 520 is, for example, identical in size and shape to the first front wiring pattern 310. In a plan view of the substrate 50A, the second intermediate wiring pattern 520 includes a cutaway portion 522 located at the same position as that of the first front wiring pattern 310. In a plan view of the substrate 50A, the second intermediate wiring pattern 520 overlaps the second front wiring pattern 320 and the second back wiring pattern 420 and a portion of the first back wiring pattern 410.

The third intermediate wiring pattern 530 is arranged along the first and fourth sides 52A and 52D of the substrate 50A and is separated from the second intermediate wiring pattern 520. In the second embodiment, the third intermediate wiring pattern 530 is, for example, identical in size and shape to the third front wiring pattern 330 and is arranged adjacent to (but separated from) the cutaway portion 522 of the second intermediate wiring pattern 520. The total area of the second intermediate wiring pattern 520 and the third intermediate wiring pattern 530 corresponds to approximately ⅔ of the area of the substrate 50A. In other words, the second intermediate wiring pattern 520 and the third intermediate wiring pattern 530 are separated from each other so that a combined form of the second intermediate wiring pattern 520 and the third intermediate wiring pattern 530 is rectangular and has approximately ⅔ of the area of the substrate 50A. In a plan view of the substrate 50A, the third intermediate wiring pattern 530 overlaps the third front wiring pattern 330 and the first back wiring pattern 410.

In the same manner as the first embodiment, the substrate 50A includes the first insulation layer 250 and the second insulation layer 260. The structure of the first insulation layer 250 and the structure of the second insulation layer 260 are the same as those of the first embodiment and will not be described in detail.

As shown in FIGS. 16 to 20, in the same manner as the first embodiment, the substrate 50A includes first to third via wirings 242, 244, and 246 extending through the first and second base members 210A and 210B and electrically connecting the first wiring layer 220 and the second wiring layer 230. In the second embodiment, the first via wiring 242 electrically connects the first front wiring pattern 310, the first intermediate wiring pattern 510, and the first back wiring pattern 410. The second via wirings 244 electrically connect the second front wiring pattern 320, the second intermediate wiring pattern 520, and the second back wiring pattern 420. The third via wiring 246 electrically connects the third front wiring pattern 330, the third intermediate wiring pattern 530, and the first back wiring pattern 410.

As shown in FIGS. 16 and 18 to 20, the substrate 50A further includes multiple (for example, four) fourth via wirings 248 electrically connecting the first intermediate wiring pattern 510 and the first back wiring pattern 410. The fourth via wirings 248 are formed from, for example, a metal material such as Cu. The layout pattern of the fourth via wirings 248 is not limited. In an example, the fourth via wirings 248 are equally arranged in the first intermediate wiring pattern 510 excluding the position of the first via wiring 242. In the second embodiment, for example, the fourth via wirings 248 are arranged in a line together with the first via wiring 242.

The second embodiment of the semiconductor light emitting device 10 has the following advantages in addition to the advantages (1-1) to (1-14) of the semiconductor light emitting device 10 in the first embodiment.

(2-1) The light emitting element 60 is reduced in size. Accordingly, the area of the first wiring region 312 (the light emitting element mount region) for mounting the light emitting element 60 is small. This imposes limitations on the number of first via wirings 242 arrangeable in the first wiring region 312. As in the first embodiment, in the second embodiment, only one first via wiring 242 is arranged in the first wiring region 312, which is located directly below the light emitting element 60. As described in the advantage (1-13) of the first embodiment, in the second embodiment, interference of the first via wiring 242 with the current flowing to the light emitting element 60 is limited. In the second embodiment, the first via wiring 242 electrically connects the first front wiring pattern 310, the first intermediate wiring pattern 510, and the first back wiring pattern 410. The first via wiring 242 is used as the heat dissipation path. However, when only one first via wiring 242 is provided, the heat dissipation property of the first via wiring 242 may be insufficient. In the second embodiment, the substrate 50A of the light emitting module 30A includes the multiple (for example, four) fourth via wirings 248 connecting the first intermediate wiring pattern 510 to the first back wiring pattern 410. The fourth via wirings 248 improve the heat dissipation property without interfering with the current flowing to the light emitting element 60. In the second embodiment, the heat dissipation property is improved as compared to the first embodiment.

### MODIFIED EXAMPLES

The embodiments described above may be modified as follows. The embodiments described above and the modified examples described below can be combined as long as the combined modifications remain technically consistent with each other.

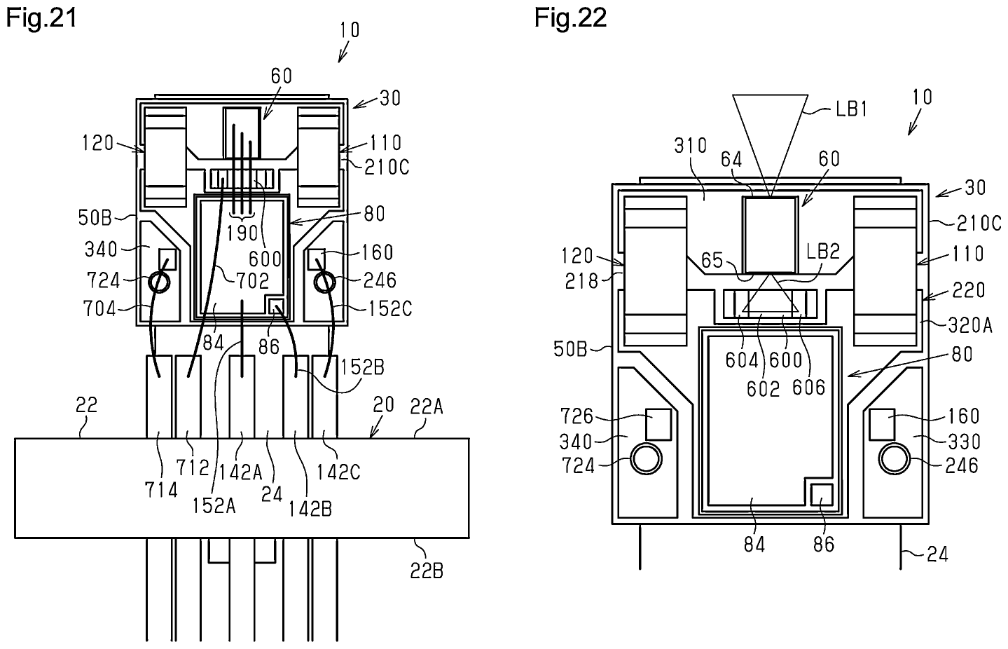

As shown in FIGS. 21 to 23, the light emitting module 30 may include a light receiving element 600 embedded in the substrate 50B and configured to receive light emitted from the light emitting element 60. The light receiving element 600 is, for example, a photodiode. As shown in FIG. 22, the light emitting element 60 includes a light outputting end surface 65 opposite to the light outputting end surface 64. The light emitting element 60 mainly emits a laser beam LB1 from the light outputting end surface 64 and also emits a laser beam LB2 from the light outputting end surface 65. In this modified example, the light receiving element 600 detects the laser beam LB2 and outputs the detected value to the drive substrate 130 (refer to FIG. 5).

In the modified example, a silicon substrate 210C is used as the base member of the substrate 50B instead of the base members 210, 210A, and 210B of the embodiments. Also, as shown in FIG. 22, a second front wiring pattern 320A is used instead of the second front wiring pattern 320 of the embodiments. The second front wiring pattern 320A is formed to expose a front surface 218 of the silicon substrate 210C in a region between the light emitting element 60 and the transistor 80. The light receiving element 600 is embedded in the silicon substrate 210C in the region between the light emitting element 60 and the transistor 80.

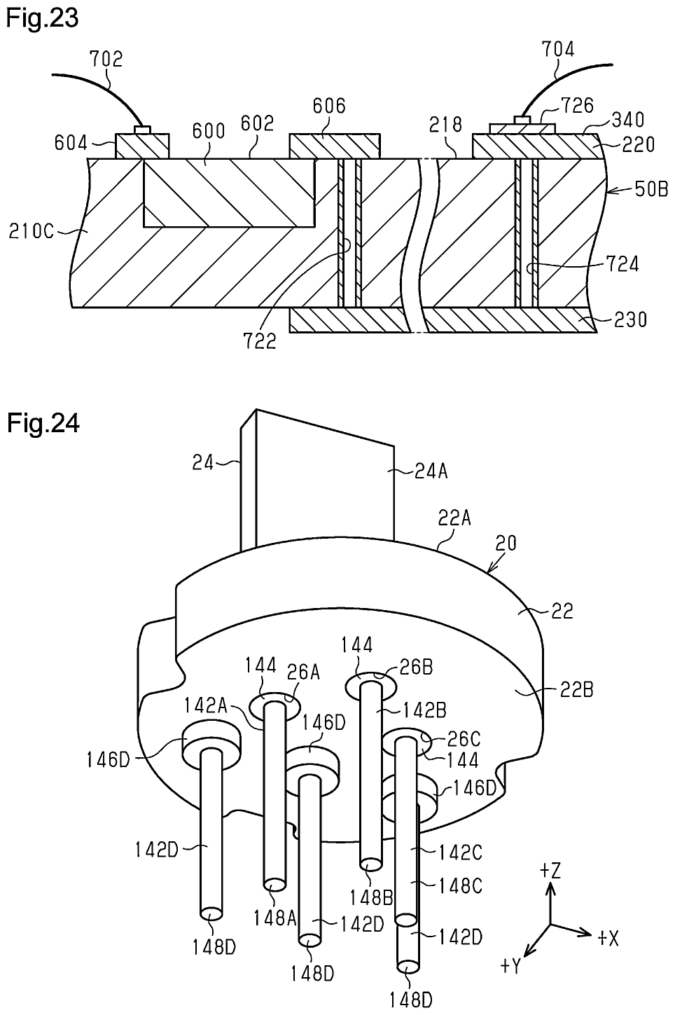

FIG. 23 is a cross-sectional view showing an example of the structure of the light receiving element 600 formed in the silicon substrate 210C. The light receiving element 600 includes a light receiving surface 602 exposed from the front surface 218 of the silicon substrate 210C and an anode electrode 604 and a cathode electrode 606 formed on the front surface 218 of the silicon substrate 210C. The anode electrode 604 of the light receiving element 600 is connected to a lead pin 712 (refer to FIG. 21) by a wire 702. The lead pin 712 is connected to the drive substrate 130 (refer to FIG. 5). The cathode electrode 606 is connected to the second wiring layer 230 by a via wiring 722 extending through the silicon substrate 210C. The second wiring layer 230 is connected to a fourth front wiring pattern 340 of the first wiring layer 220 by a via wiring 724. As shown in FIG. 22, a connection pad 726 is formed on the fourth front wiring pattern 340 from a metal plating material. The connection pad 726 is connected to a lead pin 714 (refer to FIG. 21) by a wire 704. The lead pin 714 is connected to the drive substrate 130 (refer to FIG. 5). With this structure, the light receiving element 600 detects the laser beam LB2, which is emitted from the light emitting element 60, with the light receiving surface 602 to detect a faulty operation of the light emitting element 60.

The number of lead pins (in the embodiments described above, the lead pin 142D) fixed to the back surface 22B of the base 22 and electrically connected to the heat sink 24 is not limited to one. For example, as shown in FIG. 24, three lead pins 142D may be fixed to the back surface 22B of the base 22. In this modified example, the three lead pins 142D are arranged in a line in a direction (the X-axis direction) parallel to the support surface 24A of the heat sink 24. Of the three lead pins 142D, the center lead pin 142D is fixed to a position overlapping the heat sink 24 as viewed in the thickness-wise direction (the Z-axis direction) of the base 22. The layout pattern of the lead pins 142D is not limited to that shown in FIG. 24. The number of lead pins 142D is not limited to three and may be two or four or more. As described above, multiple lead pins 142D electrically connected to the heat sink 24 further improve the heat dissipation property.

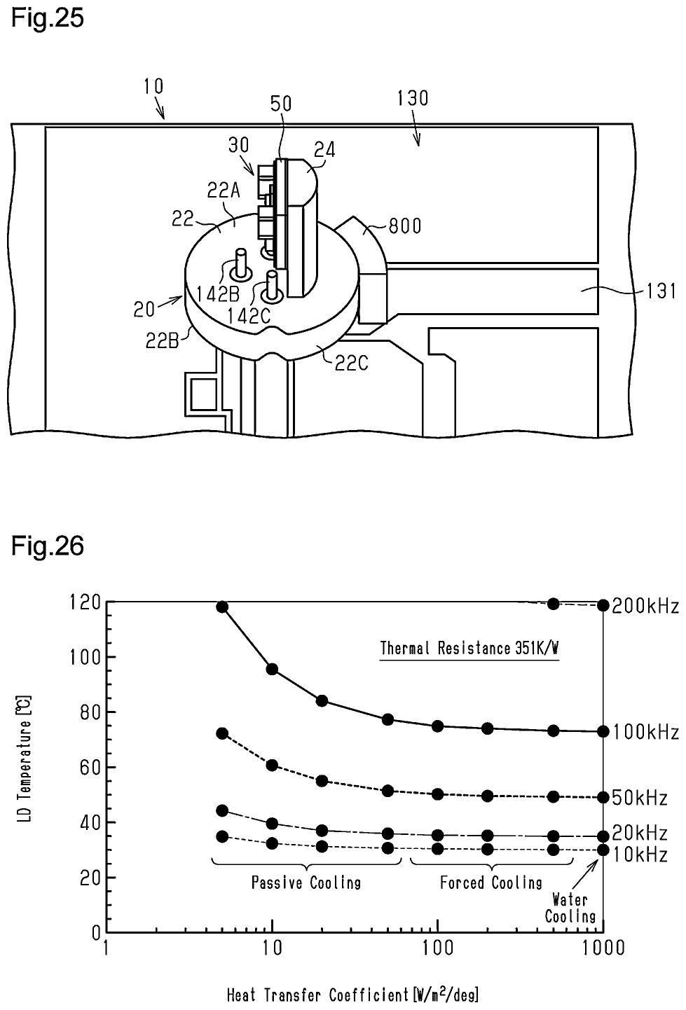

As shown in FIG. 25, a heat dissipation member 800 may be arranged in contact with a peripheral surface 22C of the base 22 and electrically connect the drive substrate 130 and the base 22. The heat dissipation member 800 is in contact with a land 131 (e.g., copper wiring pattern) of the drive substrate 130. The lead pin 142D (second lead pin), which is electrically connected to the heat sink 24, is mounted on the land 131. The material of the heat dissipation member 800 is not limited. For example, a metal material such as copper (Cu), iron (Fe), or aluminum (Al) may be used as the heat dissipation member 800. The thickness of the heat dissipation member 800 is not limited. The length of the heat dissipation member 800, which is in contact with the peripheral surface 22C of the base 22, is not limited.

In a structure in which the light emitting module 30 is mounted on the drive substrate 130 using the stem 20 and the lead pins 142A, 142B, 142C, and 142D (refer to FIG. 1), a substantial portion of the thermal resistance is caused by the lead pins 142A, 142B, 142C, and 142D. Thermal resistance will increase as the distance between the base 22 of the back surface 22B and the drive substrate 130 increases (because the terminals 148A, 148B, 148C, and 148D become longer). Such thermal resistance causes the temperature of the light emitting element 60 to increase.

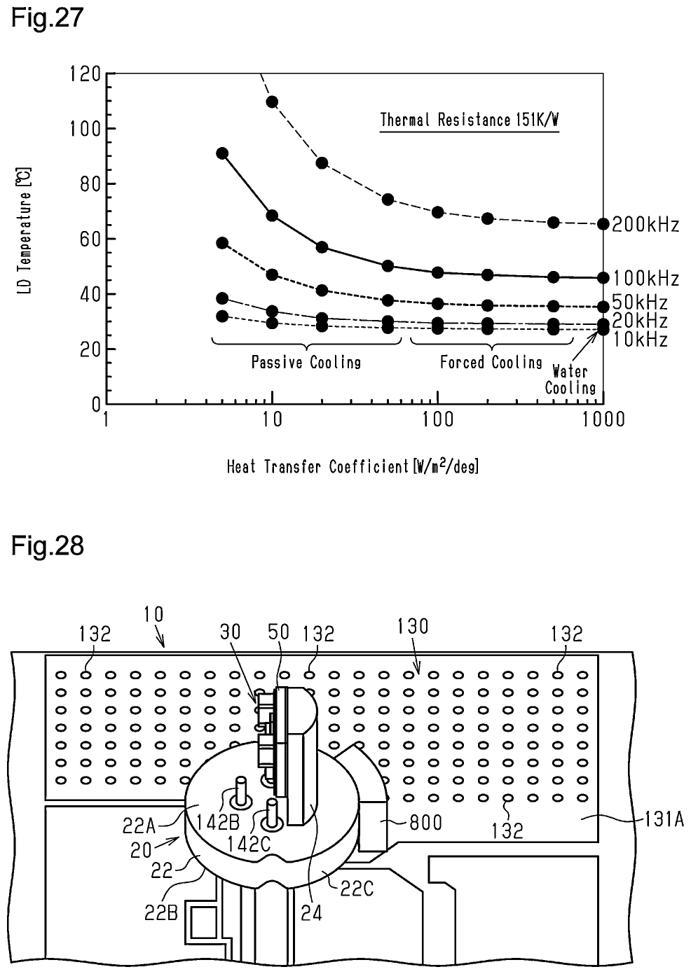

FIG. 26 is a graph showing the relationship of the heat transfer coefficient indicating heat dissipation from the back surface of the drive substrate 130 with no heat dissipation member 800, the switching frequency of the transistor 80, and the temperature (hereafter, referred to as “LD temperature”) of the light emitting element 60. FIG. 27 is a graph showing the relationship of the heat transfer coefficient when the heat dissipation member 800 is arranged, the switching frequency, and the LD temperature. The thermal conduction analysis results are shown when passive cooling is performed, forced cooling is performed, and water-cooling is performed. The heat dissipation member 800 is a Cu plate. The length of the heat dissipation member 800 is ⅛ of the perimeter of the peripheral surface 22C. The thickness of the heat dissipation member 800 is 1 mm.

As shown in FIGS. 26 and 27, when the heat dissipation member 800 is not arranged, the path (hereafter, “thermal conductive path”) from the light emitting element 60 to the back surface of the drive substrate 130 has thermal resistance of 351 K/W. When the heat dissipation member 800 is arranged, the thermal conductive path has thermal resistance of 151 K/W. Therefore, when the heat dissipation member 800 is arranged, the thermal resistance is decreased to approximately ½.

As shown in FIG. 26, when the heat dissipation member 800 is not arranged, the tolerance value of the switching frequency is 50 kHz taking into consideration the LD temperature. As shown in FIG. 27, at the switching frequency of 100 kHz, when the heat dissipation member 800 is arranged, the LD temperature is decreased by approximately 30° C. as compared to when the heat dissipation member 800 is not arranged. This shows that the heat dissipation is improved. When the heat dissipation member 800 is arranged and forced cooling is performed, the switching frequency may be set to 100 kHz.

As shown in FIG. 28, when the heat dissipation member 800 is used, the drive substrate 130 may include a land 131A in contact with the heat dissipation member 800. The land 131A may include vias 132. The land 131A is greater in area than the land 131, which is in contact with the heat dissipation member 800 shown in FIG. 25.

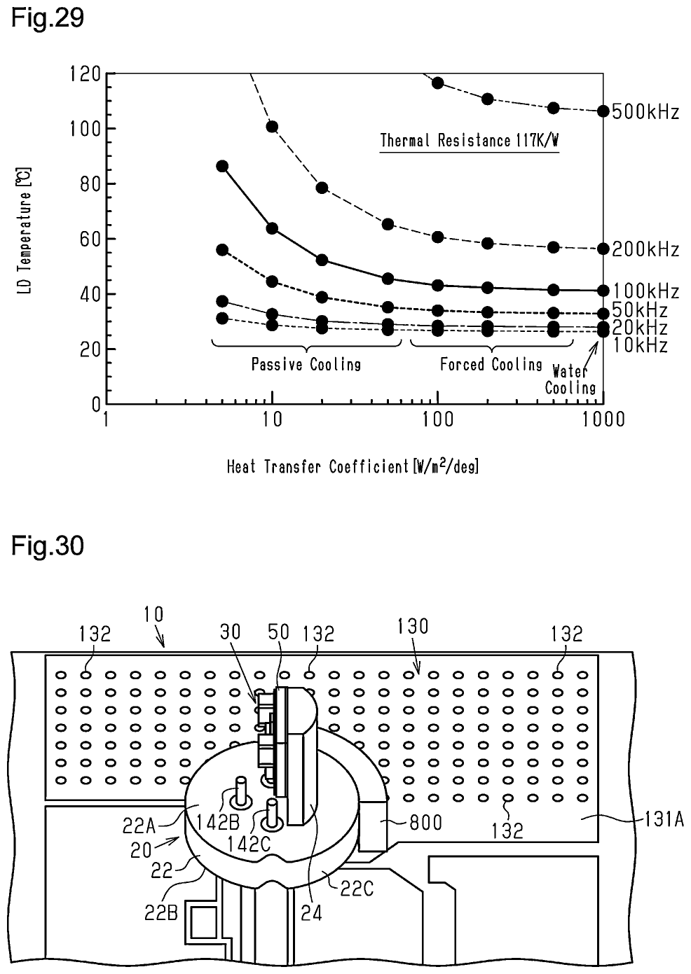

FIG. 29 is a graph showing the relationship of the heat transfer coefficient, the switching frequency, and the LD temperature when the vias 132 are arranged on the land 131A of the drive substrate 130 (the structure shown in FIG. 28). In the same manner as the structure shown in FIG. 25 and described above, the heat dissipation member 800 is a Cu plate. The length of the heat dissipation member 800 is ⅛ of the perimeter of the peripheral surface 22C. The thickness of the heat dissipation member 800 is 1 mm.

As shown in FIG. 29, when the vias 132 are arranged, the thermal resistance of the thermal conductive path is 117 K/W and lower than that when the vias 132 are not arranged (refer to FIG. 27). When the vias 132 are arranged, the LD temperature is lower by approximately 5° C. than when the vias 132 are not arranged (refer to FIG. 27) at the switching frequency of 100 kHz and 200 kHz. This shows that the heat dissipation is improved. When the vias 132 are arranged and forced cooling is performed, the switching frequency may be set to 200 kHz.

As shown in FIG. 30, the length of the heat dissipation member 800 may be ¼ of the perimeter of the peripheral surface 22C.

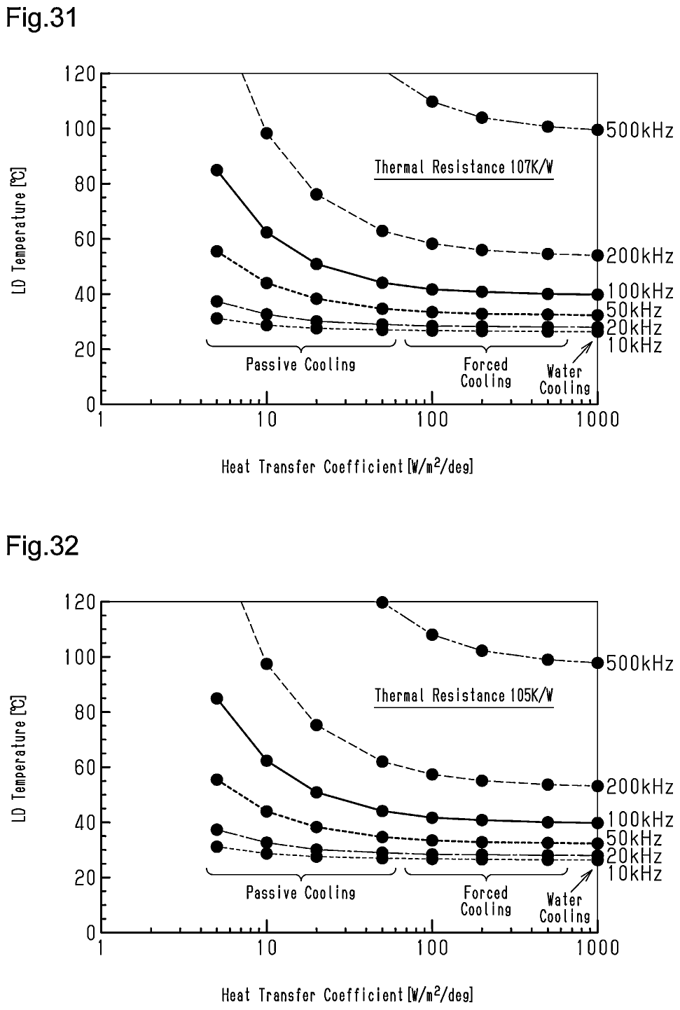

FIG. 31 is a graph showing the relationship of the heat transfer coefficient, the switching frequency, and the LD temperature when the structure is as shown in FIG. 30. In the same manner as the structure shown in FIG. 28, the heat dissipation member 800 is a Cu plate. The thickness of the heat dissipation member 800 is approximately 1 mm.

As shown in FIG. 31, when the length of the heat dissipation member 800 is ¼ of the perimeter of the peripheral surface 22C, the thermal resistance of the thermal conductive path is 107 K/W. This is almost the same as when the length of the heat dissipation member 800 is ⅛ of the perimeter of the peripheral surface 22C (refer to FIG. 29). FIG. 32 is a graph when the length of the heat dissipation member 800 is ⅓ of the perimeter of the peripheral surface 22C. In this case, the thermal resistance of the thermal conductive path is 105 K/W. This is almost the same as when the length of the heat dissipation member 800 is ⅛ of the perimeter of the peripheral surface 22C (refer to FIG. 29).

Therefore, when the material of the heat dissipation member 800 is Cu, the thickness is 1 mm, and the length is ¼ of the perimeter of the peripheral surface 22C, the thermal resistance is sufficiently reduced by the heat dissipation member 800. Under this condition, the thermal resistance of the heat dissipation member 800 is less than or equal to 0.5 K/W. When the material of the heat dissipation member 800 is Al, the thickness of the heat dissipation member 800 is set to 1.5 mm, and the length is set to ¼ of the perimeter of the peripheral surface 22C. As a result, the thermal resistance of the heat dissipation member 800 is less than or equal to 0.5 K/W. When the material of the heat dissipation member 800 is Fe, the thickness of the heat dissipation member 800 is set to be greater than or equal to 3.0 mm, and the length is set to ⅓ of the perimeter of the peripheral surface 22C. As a result, the thermal resistance of the heat dissipation member 800 is less than or equal to 0.5 K/W.

The inside of the via wirings 242, 244, 246, and 248 may be filled with a substance having a high thermal conductivity and be used as via fillings. This increases the thermal conductivity and improves the function of thermal vias. Alternatively, the via wirings 242, 244, 246, and 248 are not limited to being hollow and may be, for example, rod-shaped.

The number of the second via wirings 244 is not limited to six and may be any number. In other words, the number of the second via wirings 244 may be one or two or more.

The number of the fourth via wirings 248 is not limited to four and may be any number. In other words, the number of the second via wirings 244 may be one or two or more.

At least one of the first and second capacitors 110 and 120 of the light emitting element drive circuit 70 may be mounted on another substrate. In an example, only the vertical MOSFET (the transistor 80) may be mounted on the substrate 50.

Instead of the first and second capacitors 110 and 120, one or three or more capacitors may be used.

The number of the intermediate wiring layers 240 is not limited to one. Multiple intermediate wiring layers 240 may be arranged in the base member 210.

A protection diode (e.g., the SBD 170) that is connected in antiparallel to the light emitting element 60 may be mounted on the light emitting module 30 (e.g., the substrate 50). When the SBD 170, arranged on the drive substrate 130, is integrated with the light emitting module 30, the drive substrate 130 is reduced in size. Ultimately, the overall size of the system is reduced.

The gate driver 180, which is configured to control the driving of the transistor 80, may be mounted on the light emitting module 30 (e.g., the substrate 50). When the gate driver 180, arranged on the drive substrate 130, is integrated with the light emitting module 30, the drive substrate 130 is reduced in size. Ultimately, the overall size of the system is reduced.

In the present disclosure, the term “on” includes the meaning of “above” in addition to the meaning of “on” unless otherwise clearly indicated in the context. Therefore, for example, the phrase “first component formed on second component” is intended to mean that the first component may be formed on the second component in contact with the second component in one embodiment and that the first component may be located above the second component without contacting the second component in another embodiment. In other words, the term “on” does not exclude a structure in which another component is formed between the first component and the second component.

The Z-axis direction as referred to in the present disclosure does not necessarily have to be the vertical direction and does not necessarily have to fully conform to the vertical direction. In the structures according to the present disclosure (e.g., the structure shown in FIG. 1), “upward” and “downward” in the Z-axis direction as referred to in the present description are not limited to “upward” and “downward” in the vertical direction. For example, the X-axis direction may conform to the vertical direction. The Y-axis direction may conform to the vertical direction.

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims.

### CLAUSES

The technical aspects that are understood from the embodiments and the modified examples will be described below. The reference signs of the elements in the embodiments are given to the corresponding elements in clauses with parentheses. The reference signs used as examples to facilitate understanding, and the elements in each clause are not limited to those elements given with the reference signs.

A1. A semiconductor light emitting device (10), including:

a light emitting module (30; 30A);

a stem (20) including a conductive base (22) and a conductive heat sink (24) extending upright from the base (22), the light emitting module (30; 30A) being mounted on the heat sink (24); and

a surrounding member (40) arranged on the base (22) and surrounding the light emitting module (30; 30A) and the heat sink (24), in which

the light emitting module (30; 30A) includes
a substrate (50; 50A; 50B) mounted on the heat sink (24),
a light emitting element (60) mounted on the substrate (50; 50A; 50B), and
a light emitting element drive circuit (70) mounted on the substrate (50; 50A; 50B),

the light emitting element drive circuit (70) includes a transistor (80) configured to drive the light emitting element (60), and

the transistor (80) is a vertical MOSFET mounted on the substrate (50; 50A; 50B).

A2. The semiconductor light emitting device (10) according to clause A1, in which the light emitting element drive circuit (70) further includes a capacitor (110; 120) mounted on the substrate (50; 50A; 50B).

A3. The semiconductor light emitting device (10) according to clause A1, in which

in a plan view of the substrate (50; 50A; 50B), the transistor (80) is rectangular and includes a first side (82A) and a second side (82B) parallel to each other and a third side (82C) and a fourth side (82D) parallel to each other and connecting the first side (82A) and the second side (82B),

the light emitting element drive circuit (70) further includes
a first capacitor (110) mounted on the substrate (50; 50A; 50B) adjacent to the first side (82A) of the transistor (80) in a plan view of the substrate (50; 50A; 50B) and electrically connected to the transistor (80), and
a second capacitor (120) mounted on the substrate (50; 50A; 50B) adjacent to the second side (82B) of the transistor (80) in a plan view of the substrate (50; 50A; 50B) and electrically connected to the transistor (80),

in a plan view of the substrate (50; 50A; 50B), the third side (82C) of the transistor (80) is located between the first capacitor (110) and the second capacitor (120), and

the light emitting element (60) is arranged adjacent to the third side (82C) of the transistor (80) and electrically connected to the transistor (80) by multiple wires (190).

A4. The semiconductor light emitting device (10) according to clause A3, in which

the third side (82C) of the transistor (80) is shorter than the first side (82A) and the second side (82B) of the transistor (80), and

in a plan view of the substrate (50; 50A; 50B), the first capacitor (110) and the second capacitor (120) are separated from each other by a distance that is longer than the third side (82C) of the transistor (80).

A5. The semiconductor light emitting device (10) according to any one of clauses A1 to A4, further including:

multiple lead pins (142A, 142B, 142C, 142D) electrically connecting the light emitting module (30; 30A) and a drive substrate (130) configured to control driving of the light emitting module (30; 30A).

A6. The semiconductor light emitting device (10) according to clause A5, in which

The multiple lead pins (142A, 142B, 142C, 142D) include multiple first lead pins (142A, 142B) extending through the base (22) and electrically connected to the transistor (80) by multiple first wires (152A, 152B), and

the transistor (80) is electrically connected to the light emitting element (60) by multiple second wires (190), the multiple second wires (190) being greater in number than the multiple first wires (152A, 152B).

A7. The semiconductor light emitting device (10) according to clause A6, in which the multiple lead pins (142A, 142B, 142C, 142D) include a second lead pin (142D) fixed to the base (22) and electrically connected to the transistor (80) by the base (22), the heat sink (24), and an internal wiring structure of the substrate (50; 50A; 50B).

A8. The semiconductor light emitting device (10) according to clause A7, in which the multiple lead pins (142A, 142B, 142C, 142D) include a third lead pin (142C) configured to electrically connect the substrate (50; 50A; 50B) to a protection diode (170) that is connected in antiparallel to the light emitting element (60).

A9. The semiconductor light emitting device (10) according to clause A7 or A8, in which

the drive substrate (130) includes a land (131; 131A) on which the second lead pin (142D) is mounted, and

the land (131; 131A) includes multiple vias (132).

A10. The semiconductor light emitting device (10) according to any one of clauses A5 to A9, further including:

a heat dissipation member (800) arranged in contact with a peripheral surface (22C) of the base (22) and electrically connecting the drive substrate (130) and the base (22).

A11. The semiconductor light emitting device (10) according to any one of clauses A1 to A10, in which the transistor (80) has a chip area that is greater than or equal to 0.8 mm² and less than or equal to 4.3 mm².

A12. The semiconductor light emitting device (10) according to any one of clauses A1 to A11, in which

the substrate (50; 50A; 50B) includes an insulative base member (210; 210A, 210B),

the base member (210; 210A, 210B) includes a resin member, a silicon member, a glass member, or a ceramic member.

A13. The semiconductor light emitting device (10) according to clause A12, in which

the substrate (50; 50A; 50B) includes
a first wiring layer (220) arranged on a front surface of the base member (210; 210A, 210B),
a second wiring layer (230) arranged on a back surface of the base member (210; 210A, 210B),
multiple via wirings (242, 244, 246, 248) extending through the base member (210; 210A, 210B) and electrically connecting the first wiring layer (220) and the second wiring layer (230),
a first insulation layer (250) arranged on a front surface of the first wiring layer (220) to expose portions of the first wiring layer (220) as a light emitting element mount region (312), on which the light emitting element (60) is mounted, and a transistor mount region (322), on which the transistor (80) is mounted, and
a second insulation layer (260) arranged on a back surface of the second wiring layer (230) to expose a portion of the second wiring layer (230) as a transistor connection region (414),

the first wiring layer (220) includes
a first front wiring pattern (310) including the light emitting element mount region (312), and
a second front wiring pattern (320) separated from the first front wiring pattern (310) and including the transistor mount region (322),

the second wiring layer (230) includes
a first back wiring pattern (410), and
a second back wiring pattern (420) separated from the first back wiring pattern (410) and including the transistor connection region (414), the multiple via wirings (242, 244, 246, 248) include
a first via wiring (242) electrically connecting the first front wiring pattern (310) and the first back wiring pattern (410), and
a second via wiring (244) electrically connecting the second front wiring pattern (320) and the second back wiring pattern (420),

the first back wiring pattern (410) is arranged on the heat sink (24) with the second insulation layer (260) located between the first back wiring pattern (410) and the heat sink (24), and

the second back wiring pattern (420) is arranged on the heat sink (24) with the transistor connection region (414), exposed from the second insulation layer (260), electrically connected to the heat sink (24).

A14. The semiconductor light emitting device (10) according to clause A13, in which

the first wiring layer (220) further includes a third front wiring pattern (330) separated from the second front wiring pattern (320), and

the multiple via wirings (242, 244, 246, 248) further include a third via wiring (246) electrically connecting the third front wiring pattern (330) and the first back wiring pattern (410).

A15. The semiconductor light emitting device (10) according to clause A13 or A14, in which

the substrate (50A) further includes an intermediate wiring layer (240) arranged in the base member (210; 210A, 210B),

the intermediate wiring layer (240) includes a first intermediate wiring pattern (510) and a second intermediate wiring pattern (520),

the first via wiring (242) electrically connects the first front wiring pattern (310), the first intermediate wiring pattern (510), and the first back wiring pattern (410),

the second via wiring (244) electrically connects the second front wiring pattern (320), the second intermediate wiring pattern (520), and the second back wiring pattern (420), and

the substrate (50A) further includes a fourth via wiring (248) electrically connecting the first intermediate wiring pattern (510) and the first back wiring pattern (410).

A16. The semiconductor light emitting device (10) according to clause A15, in which the intermediate wiring layer (240) is one of multiple intermediate wiring layers arranged in the base member (210; 210A, 210B).

A17. The semiconductor light emitting device (10) according to any one of clauses A1 to A16, in which the light emitting module (30; 30A) further includes a light receiving element (600) embedded in the substrate (50B) and configured to detect light emitted from the light emitting element (60).

A18. The semiconductor light emitting device (10) according to any one of clauses A1 to A17, in which the light emitting module (30; 30A) further includes a protection diode (170) connected in antiparallel to the light emitting element (60).

A19. The semiconductor light emitting device (10) according to any one of clauses A1 to A18, in which the light emitting module (30; 30A) further includes a gate driver (180) configured to control driving of the transistor (80).

A20. The semiconductor light emitting device (10) according to any one of clauses A1 to A19, in which the surrounding member (40) and the stem (20) hermetically seal an accommodation cavity (42), configured to accommodate the light emitting module (30; 30A), in a hollow state to form a hollow sealing structure.

B1. A light emitting module (30; 30A), including:

a substrate (50; 50A; 50B);

a light emitting element (60) mounted on the substrate (50; 50A; 50B); and

a light emitting element drive circuit (70) mounted on the substrate (50; 50A; 50B), in which

the light emitting element drive circuit (70) includes a transistor (80) configured to drive the light emitting element (60),

the transistor (80) is a vertical MOSFET mounted on the substrate (50; 50A; 50B).

B2. The light emitting module (30; 30A) according to clause B 1, in which the light emitting element drive circuit (70) further includes a capacitor (110; 120) mounted on the substrate (50; 50A; 50B).

B3. The light emitting module (30; 30A) according to clause B1, in which

in a plan view of the substrate (50; 50A; 50B), the transistor (80) is rectangular and includes a first side (82A) and a second side (82B) parallel to each other and a third side (82C) and a fourth side (82D) parallel to each other and connecting the first side (82A) and the second side (82B),

the light emitting element drive circuit (70) further includes
a first capacitor (110) mounted on the substrate (50; 50A; 50B) adjacent to the first side (82A) of the transistor (80) in a plan view of the substrate (50; 50A; 50B) and electrically connected to the transistor (80), and
a second capacitor (120) mounted on the substrate (50; 50A; 50B) adjacent to the second side (82B) of the transistor (80) in a plan view of the substrate (50; 50A; 50B) and electrically connected to the transistor (80),

in a plan view of the substrate (50; 50A; 50B), the third side (82C) of the transistor (80) is located between the first capacitor (110) and the second capacitor (120), and

the light emitting element (60) is arranged adjacent to the third side (82C) of the transistor (80) and electrically connected to the transistor (80) by multiple wires (190).

B4. The light emitting module (30; 30A) according to clause B3, in which

the third side (82C) of the transistor (80) is shorter than the first side (82A) and the second side (82B) of the transistor (80), and

in a plan view of the substrate (50; 50A; 50B), the first capacitor (110) and the second capacitor (120) are separated from each other by a distance that is longer than the third side (82C) of the transistor (80).

What is claimed is:

1. A semiconductor light emitting device, comprising:
a light emitting module;
a stem including a conductive base and a conductive heat sink extending upright from the base, the light emitting module being mounted on the heat sink; and
a surrounding member arranged on the base and surrounding the light emitting module and the heat sink, wherein
the light emitting module includes
a substrate mounted on the heat sink,
a light emitting element mounted on the substrate, and
a light emitting element drive circuit mounted on the substrate,
the light emitting element drive circuit includes a transistor configured to drive the light emitting element, and
the transistor is a vertical MOSFET mounted on the substrate.

2. The semiconductor light emitting device according to claim 1, wherein the light emitting element drive circuit further includes a capacitor mounted on the substrate.

3. The semiconductor light emitting device according to claim 1, wherein
in a plan view of the substrate, the transistor is rectangular and includes a first side and a second side parallel to each other and a third side and a fourth side parallel to each other and connecting the first side and the second side,
the light emitting element drive circuit further includes
a first capacitor mounted on the substrate adjacent to the first side of the transistor in a plan view of the substrate and electrically connected to the transistor, and
a second capacitor mounted on the substrate adjacent to the second side of the transistor in a plan view of the substrate and electrically connected to the transistor,
in a plan view of the substrate, the third side of the transistor is located between the first capacitor and the second capacitor, and
the light emitting element is arranged adjacent to the third side of the transistor and electrically connected to the transistor by multiple wires.

4. The semiconductor light emitting device according to claim 3, wherein
the third side of the transistor is shorter than the first side and the second side of the transistor, and
in a plan view of the substrate, the first capacitor and the second capacitor are separated from each other by a distance that is longer than the third side of the transistor.

5. The semiconductor light emitting device according to claim 1, further comprising:
multiple lead pins electrically connecting the light emitting module and a drive substrate configured to control driving of the light emitting module.

6. The semiconductor light emitting device according to claim 5, wherein
the multiple lead pins include multiple first lead pins extending through the base and electrically connected to the transistor by multiple first wires, and
the transistor is electrically connected to the light emitting element by multiple second wires, the multiple second wires being greater in number than the multiple first wires.

7. The semiconductor light emitting device according to claim 6, wherein the multiple lead pins include a second lead pin fixed to the base and electrically connected to the transistor by the base, the heat sink, and an internal wiring structure of the substrate.

8. The semiconductor light emitting device according to claim 7, wherein the multiple lead pins include a third lead pin configured to electrically connect the substrate to a protection diode that is connected in antiparallel to the light emitting element.

9. The semiconductor light emitting device according to claim 7, wherein
the drive substrate includes a land on which the second lead pin is mounted, and
the land includes multiple vias.

10. The semiconductor light emitting device according to claim 5, further comprising:
a heat dissipation member arranged in contact with a peripheral surface of the base and electrically connecting the drive substrate and the base.

11. The semiconductor light emitting device according to claim 1, wherein the transistor has a chip area that is greater than or equal to 0.8 mm² and less than or equal to 4.3 mm².

12. The semiconductor light emitting device according to claim 1, wherein
the substrate includes an insulative base member,
the base member includes a resin member, a silicon member, a glass member, or a ceramic member.

13. The semiconductor light emitting device according to claim 12, wherein
the substrate includes
a first wiring layer arranged on a front surface of the base member,
a second wiring layer arranged on a back surface of the base member,
multiple via wirings extending through the base member and electrically connecting the first wiring layer and the second wiring layer,
a first insulation layer arranged on a front surface of the first wiring layer to expose portions of the first wiring layer as a light emitting element mount region, on which the light emitting element is mounted, and a transistor mount region, on which the transistor is mounted, and
a second insulation layer arranged on a back surface of the second wiring layer to expose a portion of the second wiring layer as a transistor connection region,
the first wiring layer includes
a first front wiring pattern including the light emitting element mount region, and
a second front wiring pattern separated from the first front wiring pattern and including the transistor mount region,
the second wiring layer includes
a first back wiring pattern, and
a second back wiring pattern separated from the first back wiring pattern and including the transistor connection region,
the multiple via wirings include
a first via wiring electrically connecting the first front wiring pattern and the first back wiring pattern, and
a second via wiring electrically connecting the second front wiring pattern and the second back wiring pattern,
the first back wiring pattern is arranged on the heat sink with the second insulation layer located between the first back wiring pattern and the heat sink, and
the second back wiring pattern is arranged on the heat sink with the transistor connection region, exposed from the second insulation layer, electrically connected to the heat sink.

14. The semiconductor light emitting device according to claim 13, wherein
the first wiring layer further includes a third front wiring pattern separated from the second front wiring pattern, and
the multiple via wirings further include a third via wiring electrically connecting the third front wiring pattern and the first back wiring pattern.

15. The semiconductor light emitting device according to claim 13, wherein
the substrate further includes an intermediate wiring layer arranged in the base member,
the intermediate wiring layer includes a first intermediate wiring pattern and a second intermediate wiring pattern,
the first via wiring electrically connects the first front wiring pattern, the first intermediate wiring pattern, and the first back wiring pattern,
the second via wiring electrically connects the second front wiring pattern, the second intermediate wiring pattern, and the second back wiring pattern, and
the substrate further includes a fourth via wiring electrically connecting the first intermediate wiring pattern and the first back wiring pattern.

16. The semiconductor light emitting device according to claim 1, wherein the light emitting module further includes a light receiving element embedded in the substrate and configured to detect light emitted from the light emitting element.

17. The semiconductor light emitting device according to claim 1, wherein the surrounding member and the stem hermetically seal an accommodation cavity, configured to accommodate the light emitting module, in a hollow state to form a hollow sealing structure.
